(19) United States
(12) Patent Application Publication
(10) Pub. No.: US 2024/0392159 A1
(43) Pub. Date: Nov. 28, 2024

(54) SURFACE TREATING AGENT, ARTICLE, METHOD FOR PRODUCING ARTICLE

(71) Applicant: AGC Inc., Tokyo (JP)

(72) Inventors: Hikaru ONO, Chiyoda-ku (JP); Motoshi AOYAMA, Chiyoda-ku (JP); Takuya IWASE, Chiyoda-ku (JP)

(73) Assignee: AGC Inc., Tokyo (JP)

(21) Appl. No.: 18/792,622

(22) Filed: Aug. 2, 2024

Related U.S. Application Data
(63) Continuation of application No. PCT/JP2023/002450, filed on Jan. 26, 2023.

(30) Foreign Application Priority Data
Feb. 4, 2022 (JP) 2022-016446

(51) Int. Cl. C09D 171/08; C09D 7/20

(52) U.S. Cl. CPC C09D 171/08; C09D 7/20

(57) ABSTRACT

Provided are a surface treating agent which is capable of forming a surface layer excellent in acid resistance and has excellent long-term storage stability, an article having the surface layer, and a method for producing the article. The surface treating agent of the present invention is a surface treating agent containing a fluorine-containing ether compound having a fluoropolyether chain and a reactive silyl group, and one or more ions selected from the group consisting of an iodide ion and a bromide ion, in which the content of the ions is 0.05 to 2.00 ppm by mass with respect to the total mass of the surface treating agent.

### INCORPORATION BY REFERENCE

This application is based upon and claims the benefit of priority from Japanese Patent Application 2022-016446 filed on Feb. 4, 2022, and PCT application No. PCT/JP2023/002450 filed on Jan. 26, 2023, the disclosure of which is incorporated herein in its entirety by reference.

### BACKGROUND

The present invention relates to a surface treating agent, an article and a method for producing an article.

It is known that a surface layer composed of a condensation product of a fluorine-containing ether compound is formed on the surface of a substrate by surface treatment using a fluorine-containing ether compound having a fluoropolyether chain and a reactive silyl group in order to impart water/oil repellency, antifouling properties, and the like to the surface of the substrate (Japanese Unexamined Patent Application Publication No. 2014-218639).

### SUMMARY

In recent years, performance required for the surface layer to be formed using the fluorine-containing ether compound has been increasing. For example, since an article having a surface layer on a substrate may be used under various environments, the surface layer is required to have further improved acid resistance.

In addition, even when a surface treating agent containing a fluorine-containing ether compound is stored for a long period of time, it is required that a decrease in performance can be suppressed, that is, the surface treating agent is excellent in long-term storage stability.

The present inventors have evaluated a surface layer formed using the surface treating agent containing the fluorine-containing ether compound with reference to the surface treating agent described in Japanese Unexamined Patent Application Publication No. 2014-218639 and thus found that there is room for improvement in the acid resistance of the surface layer.

Therefore, an object of the present invention is to provide a surface treating agent which is capable of forming a surface layer excellent in acid resistance and has excellent long-term storage stability, an article having the surface layer, and a method for producing the article.

As a result of intensive studies on the above problems, the present inventors have found that a surface treating agent containing a fluorine-containing ether compound and a predetermined amount of one or more ions selected from the group consisting of an iodide ion and a bromide ion is capable of forming a surface layer excellent in long-term storage stability and acid resistance, thus accomplishing the present invention.

In other words, the present inventors have found that the above object can be achieved by the following constitutions.

[1] A Surface Treating Agent Containing:
a fluorine-containing ether compound having a fluoropolyether chain and a reactive silyl group; and
one or more ions selected from the group consisting of an iodide ion and a bromide ion,
in which a content of the ions is 0.05 to 2.00 ppm by mass with respect to a total mass of the surface treating agent.

[2] The surface treating agent according to [1], in which the content of the ion is 0.20 to 1.50 ppm by mass with respect to the total mass of the surface treating agent.

[3] The surface treating agent according to [1] or [2], in which a content of the one or more ions selected from the group consisting of an iodide ion and a bromide ion is 0.5 to 20 ppm by mass with respect to a total mass of the fluorine-containing ether compound in the surface treating agent.

[4] The surface treating agent according to any one of [1] to [3], in which a molecular weight per fluoropolyether chain is 2,000 to 20,000.

[5] The surface treating agent according to any one of [1] to [4], in which the fluorine-containing ether compound is a compound represented by formula (A1), (A2), or (A3):

[R^{f1}—(OR^{f11})_{yl}—O—R¹]ⱼ-L¹-(R¹¹-T¹¹)ₓ₁ (A1)

(T³¹-R³¹)ₓ₃-L³-R³—(OR^{f12})_{y2}—O—R²-L²-(R²¹-T²¹)ₓ₂ (A2)

Q¹[-(OR^{f13})_{y3}—O—R⁴-L⁴-(R⁴¹-T⁴¹)ₓ₄]ᵣ₁ (A3)

in which
R^{f1} is a fluoroalkyl group having 1 to 20 carbon atoms, and when there is a plurality of R^{f1}, the plurality of R^{f1} is the same as or different from each other;
R^{f11} is a fluoroalkylene group having 1 to 6 carbon atoms, and when there is a plurality of R^{f11}, the plurality of R^{f11} is the same as or different from each other;
R¹ is an alkylene group or a fluoroalkylene group, and when there is a plurality of R¹, the plurality of R₁ is the same as or different from each other;
L¹ is a single bond or a j+x1 valent organic group optionally having N, O, S, or Si and a branch point, in which atoms bonded to R¹ and R¹¹ are each independently N, O, S, or Si, a carbon atom constituting the branch point, or a carbon atom having an oxo group (═O);
R¹¹ is an alkylene group in which an atom bonded to L¹ is optionally an etheric oxygen atom and which optionally has an etheric oxygen atom between carbon-carbon atoms;
T¹¹ is —SiR^{a11}_{z11}R^{a12}_{3-z11};
R^{a11} is a hydroxy group or a hydrolyzable group, and when there is a plurality of R^{a11}, the plurality of R^{a11} is the same as or different from each other;
R^{a12} is a non-hydrolyzable group, and when there is a plurality of R^{a12}, the plurality of R^{a12} is the same as or different from each other;
j is an integer of 1 or more;
z11 is an integer of 1 to 3;
x1 is an integer of 1 or more;
y1 is an integer of 1 or more, and when there is a plurality of y1, the plurality of y1 is the same as or different from each other;
R^{f12} is a fluoroalkylene group having 1 to 6 carbon atoms, and when there is a plurality of R^{f12}, the plurality of R^{f12} is the same as or different from each other;
R² and R³ are each independently an alkylene group or a fluoroalkylene group;
L² is a single bond or a 1+x2 valent organic group optionally having N, O, S, or Si and a branch point, in which atoms bonded to R² and R²¹ are each independently N, O, S, or Si, a carbon atom constituting the branch point, or a carbon atom having an oxo group (═O);
R²¹ is an alkylene group in which an atom adjacent to L² is optionally an etheric oxygen atom and which optionally has an etheric oxygen atom between carbon-carbon atoms;
L³ is a single bond or a 1+x3 valent organic group optionally having N, O, S, or Si and a branch point, in which atoms bonded to R³ and R³¹ are each independently N, O, S, or Si, a carbon atom constituting the branch point, or a carbon atom having an oxo group (═O);
R³¹ is an alkylene group in which an atom adjacent to L³ is optionally an etheric oxygen atom and which optionally has an etheric oxygen atom between carbon-carbon atoms;
T²¹ and T³¹ are each independently —SiR^{a21}_{Z21}R^{a22}_{3-z21};
R^{a21} is a hydroxy group or a hydrolyzable group, and when there is a plurality of R^{a21}, the plurality of R^{a21} is the same as or different from each other;
R^{a22} is a non-hydrolyzable group, and when there is a plurality of R^{a22}, the plurality of R^{a22} is the same as or different from each other;
z21 is an integer of 1 to 3;
x2 and x3 are each independently an integer of 1 or more;
y2 is an integer of 1 or more;
Q¹ is an r1 valent group having a branch point;
R^{f13} is a fluoroalkylene group having 1 to 6 carbon atoms, and when there is a plurality of R^{f13}, the plurality of R^{f13} is the same as or different from each other;
each R⁴ is independently an alkylene group or a fluoroalkylene group;
L⁴ is a single bond or a 1+x4 valent organic group optionally having N, O, S, or Si and a branch point, in which atoms bonded to R⁴ and R⁴¹ are each independently N, O, S, or Si, a carbon atom constituting the branch point, or a carbon atom having an oxo group (═O);
R⁴¹ is an alkylene group in which an atom adjacent to L⁴ is optionally an etheric oxygen atom and which optionally has an etheric oxygen atom between carbon-carbon atoms;
T⁴¹ is —SiR^{a41}_{Z41}R^{a42}_{3-Z41};
R^{a41} is a hydroxy group or a hydrolyzable group, and when there is a plurality of Rₐ₄₁, the plurality of R^{a41} is the same as or different from each other;
R^{a42} is a non-hydrolyzable group, and when there is a plurality of R^{a42}, the plurality of R^{a42} is the same as or different from each other;
z41 is an integer of 1 to 3;
x4 is an integer of 1 or more;
y3 is an integer of 1 or more; and
r1 is 3 or 4.

[6] The surface treating agent according to any one of [1] to [5], further containing a liquid medium.

[7] The surface treating agent according to [6], in which the liquid medium is a fluorine-based organic solvent.

[8] An article including a surface layer formed of the surface treating agent according to any one of [1] to [7] on a substrate.

[9] A method for producing an article, including forming a surface layer on a substrate by a dry coating method or a wet coating method using the surface treating agent according to any one of [1] to [7].

According to the present invention, it is possible to provide a surface treating agent which is capable of forming a surface layer excellent in acid resistance and has excellent long-term storage stability, an article having the surface layer, and a method for producing the article.

### DESCRIPTION OF EMBODIMENTS

In the present specification, a group represented by formula (g1) is referred to as group (g1). A compound represented by formula (A1) is referred to as compound (A1). The same applies to compounds represented by other formulae.

A fluoroalkyl group is a generic term for a combination of a perfluoroalkyl group and a partial fluoroalkyl group. The perfluoroalkyl group means a group having all hydrogen atoms in an alkyl group substituted with fluorine atoms. The partial fluoroalkyl group is an alkyl group having one or more hydrogen atoms substituted with fluorine atoms and one or more hydrogen atoms. That is, the fluoroalkyl group is an alkyl group having one or more fluorine atoms.

The term “reactive silyl group” collectively refers to a hydrolyzable silyl group and a silanol group (Si—OH), and the “hydrolyzable silyl group” means a group capable of forming a silanol group by hydrolysis reaction.

An “organic group” means a hydrocarbon group that may have a substituents and a heteroatom or another bond in a carbon chain.

The “hydrocarbon group” is a group consisting of a carbon atom and a hydrogen atom, the group composed of an aliphatic hydrocarbon group (e.g., as a bivalent aliphatic hydrocarbon group, a linear alkylene group, a branched alkylene group, or a cycloalkylene group), an aromatic hydrocarbon group (e.g., as a bivalent aromatic hydrocarbon group, a phenylene group), or a combination thereof.

A “surface layer” means a layer formed on a substrate.

The “molecular weight” of a fluoropolyether chain is the number average molecular weight calculated from the number (average value) of oxyfluoroalkylene units on the basis of terminal groups determined by ¹H-NMR and ¹⁹F-NMR.

The expression “to” indicating a numerical range is meant to include numerical values given before and after it as a lower limit value and an upper limit value. In numerical ranges described in a stepwise manner in the present specification, an upper limit value or a lower limit value given within a certain numerical range may be replaced with an upper limit value or a lower limit value of another numerical range described in a stepwise manner. In the numerical ranges described in the present specification, the upper limit value or the lower limit value given within a certain numerical range may also be replaced with a value shown in Examples.

The term “ppm” means “parts-per-million (10⁻⁶)”. For example, 1.0 ppm by mass represents 1.0×10⁻⁴% by mass.

### [Surface Treating Agent]

The surface treating agent of the present invention (hereinafter also referred to as “the present surface treating agent”) is a surface treating agent containing a fluorine-containing ether compound having a fluoropolyether chain and a reactive silyl group; and one or more ions selected from the group consisting of an iodide ion and a bromide ion (hereinafter also referred to as “specific ion”), in which the content of the specific ion is 0.05 to 2.00 ppm by mass with respect to the total mass of the surface treating agent.

It is presumed that the acid resistance of the surface layer obtained using the surface treating agent is improved when the content of the specific ion in the surface treating agent is 0.05 ppm by mass or more, as shown in the section of Examples described later.

On the other hand, when the content of the specific ion in the surface treating agent is too large, the reactivity of the reactive silyl group becomes high, whereby reactive silyl groups at the terminal of the perfluoropolyether chain react with each other to progress condensation when the surface treating agent is stored for a long period of time. Therefore, it is presumed that the friction durability of the surface layer formed using the surface treating agent after long-term storage is lower than that of the surface layer formed using the surface treating agent before long-term storage.

With respect to such problems, it is presumed that the surface treating agent has excellent long-term storage stability since the content of the specific ions in the surface treating agent is in the range of 0.05 to 2.00 ppm by mass, and the acid resistance of the surface layer obtained using the surface treating agent is improved.

### <Fluorine-Containing Ether Compound>

The fluorine-containing ether compound has a fluoropolyether chain and a reactive silyl group.

Since the fluorine-containing ether compound has a fluoropolyether chain, a surface layer obtained by using the fluorine-containing ether compound has excellent water/oil repellency and fingerprint stain removability.

The fluorine-containing ether compound has a reactive silyl group. Since the reactive silyl group is strongly chemically bonded to a substrate, the resulting surface layer has excellent friction durability.

The fluoropolyether chain is a group having two or more oxyfluoroalkylene units.

The fluoropolyether chain may have a hydrogen atom. From the viewpoint of more excellent friction durability and fingerprint stain removability of the surface layer, the proportion of fluorine atoms in the fluoropolyether chain represented by the following expression (I) is preferably 60% or more, more preferably 80% or more, and substantially 100%, that is, a perfluoropolyether chain is even more preferable. When the content of fluorine atoms is 60% or more, the amount of fluorine in the fluoropolyether chain is increased to further improve the lubricity and fingerprint removability.

Expression (I): Proportion of fluorine atoms (%)=(number of fluorine atoms)/{(number of fluorine atoms)+(number of hydrogen atoms)}×100

The molecular weight per fluoropolyether chain is preferably 2,000 to 20,000, more preferably 2,500 to 15,000, and even more preferably 3,000 to 10,000, from the viewpoint of achieving both fingerprint stain removability and lubricity of the surface layer. When the molecular weight of the fluoropolyether chain is 2,000 or more, the flexibility of the fluoropolyether chain is improved, as well as an increase in the amount of fluorine in the molecule, to further improve the lubricity and fingerprint removability. On the other hand, when the molecular weight of the fluoropolyether chain is 20,000 or less, the friction durability of the surface layer is more excellent.

The fluoropolyether chain is preferably of structure (f1). (OR^{f})_{y}(f1)
R^{f} is a fluoroalkylene group having 1 to 6 carbon atoms, and a plurality of R^{f} is the same as or different from each other.
y may be an integer of 2 or more, preferably 2 to 200.
(OR^{f})_{y} preferably has a structure represented by formula (f2):

-[(OG^{fl})ₘ₁(OG^{f2})ₘ₂(OG^{f3})ₘ₃(OG^{f4})ₘ₄(OG_{f5})ₘ₅(OG_{f6})ₘ₆]- (f2)
in which
G^{f1} is a fluoroalkylene group having 1 carbon atom;
G^{f2} is a fluoroalkylene group having 2 carbon atom;
G^{f3} is a fluoroalkylene group having 3 carbon atom;
G^{f4} is a fluoroalkylene group having 4 carbon atom;
G^{f5} is a fluoroalkylene group having 5 carbon atom;
G^{f6} is a fluoroalkylene group having 6 carbon atom;
m1, m2, m3, m4, m5, and m6 each independently represent an integer of 0 or 1 or more; and
m1+m2+m3+m4+m5+m6 is preferably an integer of 2 to 200.

Note that (OG^{f1}) to (OG^{f6}) in formula (f2) are bonded in any order. m1 to m6 in formula (f2) respectively represent the number of (OG^{f1}) to (OG^{f6}), not the arrangement. For example, (OG^{f5})ₘ₅ represents that the number of (OG^{f5}) is m5, not the block arrangement structure of (OG^{f5})ₘ₅. Similarly, the order of description of (OG^{f1}) to (OG^{f6}) does not represent the binding order of the respective units.

The fluoroalkylene group having 3 to 6 carbon atoms may be a linear fluoroalkylene group or a fluoroalkylene group having a branched or cyclic structure.

Specific examples of G^{f1} include —CF₂— and —CHF—.

Specific examples of G^{f2} include —CF₂CF₂—, —CHFCF₂—, —CHFCHF—, —CH₂CF₂—, —CH₂CHF—.

Specific examples of G^{f3} include —CF₂CF₂CF₂—, —CF₂CHFCF₂—, —CF₂CH₂CF₂—, —CHFCF₂CF₂—, —CHFCHFCF₂—, —CHFCHFCHF—, —CHFCH₂CF₂—, —CH₂CF₂CF₂—, —CH₂CHFCF₂—, —CH₂CH₂CF₂—, —CH₂CF₂CHF—, —CH₂CHFCHF—, —CH₂CH₂CHF—, —CF(CF₃)—CF₂—, —CF(CHF₂)—CF₂—, —CF(CH₂F)—CF₂—, —CF(CH₃)—CF₂—, —CF(CF₃)—CHF—, —CF(CHF₂)˜CHF—, —CF(CH₂F)—CHF—, —CF(CH₃)—CHF—, —CF(CF₃)—CH₂—, —CF(CHF₂)—CH₂—, —CF(CH₂F)—CH₂—, —CF(CH₃)—CH₂—, —CH(CF₃)—CF₂—, —CH(CHF₂)—CF₂—, —CH(CH₂F)—CF₂—, —CH(CH₃)—CF₂—, —CH(CF₃)˜CHF—, —CH(CHF₂)—CHF—, —CH(CH₂F)—CHF—, —CH(CH₃)—CHF—, —CH(CF₃)—CH₂—, —CH(CHF₂)—CH₂—, and —CH(CH₂F)—CH₂—.

Specific examples of G^{f4} include —CF₂CF₂CF₂CF₂—, —CHFCF₂CF₂CF₂—, —CH₂CF₂CF₂CF₂—, —CF₂CHFCF₂CF₂—, —CHFCHFCF₂CF₂—, —CH₂CHFCF₂CF₂—, —CF₂CH₂CF₂CF₂—, —CHFCH₂CF₂CF₂—, —CH₂CH₂CF₂CF₂—, —CHFCF₂CHFCF₂—, —CH₂CF₂CHFCF₂—, —CF₂CHFCHFCF₂—, —CHFCHFCHFCF₂—, —CH₂CHFCHFCF₂—, —CF₂CH₂CHFCF₂—, —CHFCH₂CHFCF₂—, —CH₂CH₂CHFCF ₂—, —CF₂CH₂CH₂CF₂—, —CHFCH₂CH₂CF₂—, —CH₂CH₂CH₂CF₂—, —CHFCH₂CH₂CHF—, —CH₂CH₂CH₂CHF—, and -cycloC₄F₆—.

Specific examples of G^{f5} include —CF₂CF₂CF₂CF₂CF₂—, —CHFCF₂CF₂CF₂CF₂—, —CH₂CHFCF₂CF₂CF₂—, —CF₂CHFCF₂CF₂CF₂—, —CHFCHFCF₂CF₂CF₂—, —CF₂CH₂CF₂CF₂CF₂—, —CHFCH₂CF₂CF₂CF₂—, —CH₂CH₂CF₂CF₂CF₂—, —CF₂CF₂CHFCF₂CF₂—, —CHFCF₂CHFCF₂CF₂—, —CH₂CF₂CHFCF₂CF₂—, —CH₂CF₂CF₂CF₂CH₂—, and -cycloC₆F₈—.

Specific examples of G^{f6} include —CF₂CF₂CF₂CF₂CF₂CF₂—, —CF₂CF₂CHFCHFCF₂CF₂—, —CHFCF₂CF₂CF₂CF₂CF₂—, —CHFCHFCHFCHFCHFCHF—, —CHFCF₂CF₂CF₂CF₂CH₂—, —CH₂CF₂CF₂CF₂CF₂CH₂— and -cycloC₆F₁₀—.

Here, -cycloC₄F₆— means a perfluorocyclobutanediyl group, specific examples of which include a perfluorocyclobutane-1,2-diyl group, and a perfluorocyclobutane-1,3-diyl group.-cycloC₆F₈— means a perfluorocyclopentandiyl group, specific examples of which include a perfluorocyclopentane-1,3-diyl group.-cycloC₆F₁₀— means a perfluorocyclohexanediyl group, specific examples of which include a perfluorocyclohexane-1,4-diyl group.

(OR^{f})_{y} preferably has any one of structures represented by formulae (f3) to (f5) from the viewpoint of more excellent water/oil repellency, friction durability, and fingerprint stain removability, more preferably has a structure represented by formula (f3) from the viewpoint of more excellent alkali resistance, and even more preferably has a structure represented by (OCF₂)ₘ₁, (OCF₂CF₂)m₂.

(OG^{f1})ₘ₁-(OG^{f2})ₘ₂ (f3)

(OG^{f2})ₘ₂-(OG^{f4})ₘ₄ (f4)

(OG^{f3})ₘ₃ (f5)
where each symbol in formulae (f3) to (f5) is the same as in formula (f2) above.

In Formula (f3) and Formula (f4), (OG^{f1}) and (OG^{f2}), and (OG^{f2}) and (OG^{f4}) are bonded in any order, respectively. For example, in formula (G2), (OG^{f1}) and (OG^{f2}) may be alternately arranged, and (OG^{f1}) and (OG^{f2}) may each be arranged in a block or randomly. The same applies to formula (f5).

In formula (f3), m1 is preferably 1 to 30 and more preferably 1 to 20. m2 is preferably 1 to 30 and more preferably 1 to 20.

In formula (f4), m2 is preferably 1 to 30 and more preferably 1 to 20. m4 is preferably 1 to 30 and more preferably 1 to 20.

In formula (f5), m3 is preferably 1 to 30 and more preferably 1 to 20.

In the fluoropolyether chain (OR) y, the proportion of fluorine atoms [{number of fluorine atoms/(number of fluorine atoms+number of hydrogen atoms)}×100(%)] is preferably 60% or more, more preferably at 70% or more, and even more preferably 80% or more, from the viewpoint of excellent water/oil repellency and fingerprint removability.

The molecular weight of the fluoropolyether chain (OR), moiety is preferably 2,000 to 20,000, more preferably 2,500 to 15,000, and even more preferably 3,000 to 10,000, from the viewpoint of friction durability.

The reactive silyl group is preferably a group (g1):

—SiR^{a1}_{z1}R^{a2}_{3-z1} (g1)
in which
R^{a1} is a hydroxy group or a hydrolyzable group, and when there is a plurality of R^{a1}, the plurality of R^{a1} is the same as or different from each other;
R^{a2} is a non-hydrolyzable group, and when there is a plurality of R^{a2}, the plurality of R^{a2} is the same as or different from each other;
z1 is an integer of 1 to 3.
when R^{a1} is a hydroxy group, it forms a silanol (Si—OH) group together with a Si atom. The hydrolyzable group is a group converted to a hydroxy group (i.e., a silanol group) by hydrolysis reaction. Silanol groups further react between molecules to form Si—O—Si bonds. A silanol group undergoes dehydration condensation reaction with a hydroxy group (substrate (or underlying layer)-OH) on the surface of a substrate (or underlying layer) to form a chemical bond (substrate (or underlying layer)-O—Si). The fluorine-containing ether compound has excellent friction durability after formation of the surface layer due to having one or more groups (g1).

Examples of the hydrolyzable group of R^{a1} include an alkoxy group, an aryloxy group, a halogen atom, an acyl group, an acyloxy group, and an isocyanate group (—NCO). The alkoxy group is preferably an alkoxy group having 1 to 4 carbon atoms. The acyl group is preferably an acyl group having 1 to 6 carbon atoms. The acyloxy group is preferably an acyloxy group having 1 to 6 carbon atoms.

R^{a1} is preferably an alkoxy group having 1 to 4 carbon atoms or a halogen atom from the viewpoint of easy production of the fluorine-containing ether compound. The alkoxy group in R^{a1} is preferably an alkoxy group having 1 to 4 carbon atoms from the viewpoint of excellent storage stability of the fluorine-containing ether compound and suppression of outgassing during reaction, more preferably an ethoxy group from the viewpoint of long-term storage stability, and even more preferably a methoxy group from the viewpoint of shortening the hydrolysis reaction time. Alternatively, the halogen atom is preferably a chlorine atom.

Examples of the non-hydrolyzable group of R^{a2} include a hydrogen atom or a monovalent hydrocarbon group. Examples of the hydrocarbon group include an alkyl group, a cycloalkyl group, an alkenyl group, and an allyl group; and an alkyl group is preferable from the viewpoint of ease of production and the like. The number of carbon atoms in the hydrocarbon group is preferably 1 to 6, more preferably 1 to 3, and even more preferably 1 to 2 from the viewpoint of ease of production and the like.

z1 may be an integer of 1 to 3, preferably 2 or 3, and more preferably 3 from the viewpoint of adhesion to the substrate (or underlying layer).

Specific examples of the group (g1) include —Si(OCH₃)₃, —SiCH₃(OCH₃)₂, —Si(OCH₂CH₃)₃, —SiCl₃, —Si(OCOCH₃)₃, and —Si(NCO)₃. —Si(OCH₃)₃ is preferable from the viewpoint of ease of handling in production.

Note that when there is a plurality of groups (g1) in one molecule, the plurality of groups (g1) is the same as or different from each other.

In the fluorine-containing ether compound, the fluoropolyether chain and the group (g1) are bonded directly or via a linking group. Examples of the linking group include a divalent or higher organic group.

The number of fluoropolyether chains in one molecule of the fluorine-containing ether compound may be one or may be two or more. The number of fluoropolyether chains in one molecule is preferably 1 to 20, more preferably 1 to 10, and even more preferably 1 to 4 from the viewpoint of ease of synthesis and the like.

In addition, the number of groups (g1) in one molecule of the fluorine-containing ether compound may be one or may be two or more. The number of groups (g1) is preferably 1 to 32, more preferably 1 to 18, and even more preferably 2 to 12 from the viewpoint of achieving both friction durability and water/oil repellency.

Note that when there is a plurality of fluoropolyether chains, the plurality of the fluoropolyether chains is the same as or different from each other. When there is a plurality of groups (g1), the groups (g1) are the same as or different from each other.

The fluorine-containing ether compound may be any compound satisfying the above constitution. From the viewpoint of ease of synthesis, ease of handling of the compound, and the like, in particular, a compound represented by formula (A1), formula (A2), or formula (A3) below is preferable:

[R^{f1}—(OR^{f11})_{yl}—O—R¹]ⱼ-L¹-(R¹¹-T¹¹)ₓ₁ (A1)

(T³¹-R³¹)ₓ₃-L³-R³—(OR^{f12})_{y2}—O—R²-L²-(R²¹-T²¹)ₓ₂ (A2)

Q¹[-(OR^{f13})_{y3}—O—R⁴-L⁴-(R⁴¹-T⁴¹)ₓ₄]ᵣ₁ (A3)
in which R^{f1} is a fluoroalkyl group having 1 to 20 carbon atoms, and when there is a plurality of R^{f1}, the plurality of R^{f1} is the same as or different from each other;
R^{f11} is a fluoroalkylene group having 1 to 6 carbon atoms, and when there is a plurality of R^{f11}, the plurality of R^{f11} is the same as or different from each other;
R¹ is an alkylene group or a fluoroalkylene group, and when there is a plurality of R¹, the plurality of R¹ is the same as or different from each other;
L¹ is a single bond or a j+x1 valent organic group optionally having N, O, S, or Si and a branch point, in which atoms bonded to R¹ and R¹¹ are each independently N, O, S, or Si, a carbon atom constituting the branch point, or a carbon atom having an oxo group (═O);
R¹¹ is an alkylene group in which an atom bonded to L¹ is optionally an etheric oxygen atom and which optionally has an etheric oxygen atom between carbon-carbon atoms;
T¹¹ is —SiR^{a11}_{z11}R^{a12}_{3-z11};
R^{a11} is a hydroxy group or a hydrolyzable group, and when there is a plurality of R^{a11}, the plurality of R^{a11} is the same as or different from each other;
R^{a12} is a non-hydrolyzable group, and when there is a plurality of R^{a12}, the plurality of R^{a12} is the same as or different from each other;
j is an integer of 1 or more;
z11 is an integer of 1 to 3;
x1 is an integer of 1 or more;
y1 is an integer of 1 or more, and when there is a plurality of y1, the plurality of y1 is the same as or different from each other;
R^{f12} is a fluoroalkylene group having 1 to 6 carbon atoms, and when there is a plurality of R^{f12}, the plurality of R^{f12} is the same as or different from each other;
R² and R³ are each independently an alkylene group or a fluoroalkylene group;
L² is a single bond or a 1+x2 valent organic group optionally having N, O, S, or Si and a branch point, in which atoms bonded to R² and R²¹ are each independently N, O, S, or Si, a carbon atom constituting the branch point, or a carbon atom having an oxo group (═O);
R²¹ is an alkylene group in which an atom adjacent to L² is optionally an etheric oxygen atom and which optionally has an etheric oxygen atom between carbon-carbon atoms;
L³ is a single bond or a 1+x3 valent organic group optionally having N, O, S, or Si and a branch point, in which atoms bonded to R³ and R³¹ are each independently N, O, S, or Si, a carbon atom constituting the branch point, or a carbon atom having an oxo group (═O);
R³¹ is an alkylene group in which an atom adjacent to L³ is optionally an etheric oxygen atom and which optionally has an etheric oxygen atom between carbon-carbon atoms;
T²¹ and T³¹ are each independently-SiR^{a21}_{z21}Ra^{a21}_{3-z21};
R^{a21} is a hydroxy group or a hydrolyzable group, and when there is a plurality of R^{a21}, the plurality of R^{a21} is the same as or different from each other;
R^{a22} is a non-hydrolyzable group, and when there is a plurality) of Rₐ₂₂, the plurality of R^{a22} is the same as or different from each other;
z21 is an integer of 1 to 3;
x2 and x3 are each independently an integer of 1 or more;
y2 is an integer of 1 or more;
Q¹ is an r1 valent group having a branch point;
R^{f13} is a fluoroalkylene group having 1 to 6 carbon atoms, and when there is a plurality of R^{f13}, the plurality of R^{f13} is the same as or different from each other;
each R⁴ is independently an alkylene group or a fluoroalkylene group;
L⁴ is a single bond or a 1+x4 valent organic group optionally having N, O, S, or Si and a branch point, in which atoms bonded to R⁴ and R⁴¹ are each independently N, O, S, or Si, a carbon atom constituting the branch point, or a carbon atom having an oxo group (═O);
R⁴¹ is an alkylene group in which an atom adjacent to L⁴ is optionally an etheric oxygen atom and which optionally has an etheric oxygen atom between carbon-carbon atoms;
T⁴¹ is —SiR^{a41}_{z41}R^{a42}_{3-z41};
R^{a41} is a hydroxy group or a hydrolyzable group, and when there is a plurality of R^{a41}, the plurality of R^{a41} is the same as or different from each other;
R^{a42} is a non-hydrolyzable group, and when there is a plurality of R^{a42}, the plurality of R^{a42} is the same as or different from each other;
z41 is an integer of 1 to 3;
x4 is an integer of 1 or more;
y3 is an integer of 1 or more; and
r1 is 3 or 4.

Hereinafter, the composition of each compound is described, but symbols having the same structure indicate the same, which may be referred to by replacing them as appropriate.

### (Compound (A1))

Compound (A1) has a structure represented by formula (A1):

[R^{f1}—(OR^{f11})_{y1}—O—R¹]ⱼ-L¹-(R¹¹-T¹¹)ₓ₁ (A1)

where each symbol in formula (A1) is as described above.
R^{f1} is a fluoroalkyl group having 1 to 20 carbon atoms. The fluoroalkyl group may be linear or may have a branched and/or cyclic structure. A linear fluoroalkyl group is preferable from the viewpoint of friction durability. From the viewpoint of ease of synthesis, for example, the number of carbon atoms in the fluoroalkyl group is preferably 1 to 6 and more preferably 1 to 3.
R^{f11} and yl in (OR^{f11})_{yl} are the same as R^{f} and y in formula (f1) above, respectively, and preferred aspects are also the same.
R¹ is an alkylene group or a fluoroalkylene group. The alkylene group and fluoroalkylene group in R¹ may be linear or may have a branched and/or cyclic structure. From the viewpoint of ease of synthesis and the like, a linear or branched alkylene group or fluoroalkylene group is preferable, and an alkylene group or fluoroalkylene group having a methyl group or fluoromethyl group as a linear or branched group is more preferred. The number of carbon atoms in R¹ is preferably 1 to 6 and more preferably 1 to 3. When L¹ is a single bond, R¹ is directly bonded to R¹¹. In this case, the carbon atom bonded to R¹¹ in R¹ is bonded to at least one fluorine atom or fluoroalkyl group.
j represents the number of [R^{f1}—(OR^{f11})_{yl}—O—R¹] in one molecule, may be an integer of 1 or more, preferably 1 to 20, more preferably 1 to 10, and even more preferably 1 to 4.
R¹¹ is an alkylene group in which an atom bonded to L¹ is optionally an etheric oxygen atom and which optionally has an etheric oxygen atom between carbon-carbon atoms.

The alkylene group in R¹¹ may be linear or may have a branched and/or cyclic structure. From the viewpoint that compound (A1) is likely to be densely arranged in the formation of the surface layer, an alkylene group having a methyl group as a linear or branched group is preferable, and a linear alkylene group is more preferable.

Specifically, R¹¹ is represented by formula (g2):

*—(O)ₐ₁—(R^{g2}O)ₐ₂—R^{g2}—** (g2)
in which
R^{g2} is an alkylene group having one or more carbon atoms, and a plurality of R^{g2} is the same as or different from each other;
a1 is 0 or 1;
a2 is an integer of 0 or more;
*is a bonding hand which is bonded to L¹; and
**is a bonding hand which is bonded to T¹¹.

When a1 is 0, an atom having the bonding hand*is a carbon atom, and when a1 is 1, an atom having the bonding hand*is an oxygen atom. In compound (A1), a1 may be either 0 or 1 and may be appropriately selected in view of, for example, synthesis.
a2 represents the number of repetitions of R⁸²⁰, and is preferably 0 to 6, more preferably 0 to 3, and even more preferably 0 or 1 from the viewpoint of durability as a surface layer and the like.
R¹¹ is even more preferably a group represented by formula (g3) from the viewpoint of more excellent in water/oil repellency and fingerprint stain removability as a surface layer, as well as excellent in durability such as friction durability:

*—(O)ₐ₁—R^{g3}—** (g3)
in which
R &3 is an alkylene group;
a1, *, and ** are the same as in formula (g2).

The alkylene group in R^{g3} may be linear or may have a branched and/or cyclic structure. From the viewpoint that compound (A1) is likely to be densely arranged in the formation of the surface layer, a linear alkylene group is preferable. The number of carbon atoms in R^{g3} may be one or more, and is preferably 1 to 18, more preferably 1 to 12, and even more preferably 1 to 6.

T¹¹ is —SiR^{a11}_{z11}R^{a12}_{3-z11}, R^{a11}, R^{a12}, z11 are the same as R^{a1}, R^{a2}, and z1 constituting the group (g1), respectively, and preferred aspects are also the same.

x1 represents the number of R¹¹-T¹¹ in one molecule may be an integer of 1 or more, preferably 1 to 32, more preferably 1 to 18, and even more preferably 2 to 12.

L¹ is a single bond or a j+x1 valent group optionally having N, O, S, or Si and a branch point, in which atoms bonded to R¹ and R¹¹ are each independently N, O, S, or Si, a carbon atom constituting the branch point, or a carbon atom having an oxo group (═O). Note that the atoms bonded to R¹ and R¹¹ may be the same or different atoms.

When L¹ is a single bond, R¹ and R¹¹ in formula (A1) are directly bonded, and compound (A1) is represented by formula (A1′):

R^{f1}—(OR^{f11})_{yl}—O—R¹—R¹¹-T¹¹ (A1′)
where each symbol in formula (A1′) is the same as in formula (A1).

When L¹ is a trivalent or higher-valent group, L¹ has at least one branch point selected from the group consisting of C, N, Si, a cyclic structure, and a (j+x1) valent organopolysiloxane residue (hereinafter referred to as “branch point P¹”).

When N is a branch point P¹, the branch point P¹ is represented by, for example, *—N(—**)₂ or (*—)₂N—**, where*is a bonding hand on the R¹ side, and ** is a bonding hand on the R¹¹ side.

When C is the branch point P¹, the branch point P¹ is represented by, for example, *—C(—**)₃, (*—)₂C(—**)₂, (*—)₃C—**, *—CR²⁹ (—**)₂, or (*—)₂CR²⁹—**, where*is a bonding hand on the R¹ side; ** is a bonding hand on the R¹¹ side; and R²⁹ is a monovalent group such as a hydrogen atom, a hydroxy group, an alkyl group, and an alkoxy group.

When Si is the branch point P¹, the branch point P¹ is represented by, for example, *—Si(—**)₃, (*—)₂Si(—**)₂, (*—)₃Si—**, *—SiR²⁹ (—**)₂, or (*—)₂SiR²⁹.**, where*is a bonding hand on the R¹ side, ** is a bonding hand on the R¹¹ side, and R²⁹ is a monovalent group such as a hydrogen atom, a hydroxy group, an alkyl group, and an alkoxy group.

The cyclic structure constituting the branch point P¹ is preferably one selected from the group consisting of a 3- to 8-membered aliphatic ring, a 3- to 8-membered aromatic ring, a 3- to 8-membered heterocyclic ring, and a fused ring composed of two or more of these rings, and more preferably a cyclic structure represented by formulae below, from the viewpoint of easy production of the fluorine-containing ether compound and further excellent friction durability, light resistance, and chemical resistance of the surface layer. The cyclic structure may have a substituent such as a halogen atom, an alkyl group (which may contain an etheric oxygen atom between carbon-carbon atoms), a cycloalkyl group, an alkenyl group, an allyl group, an alkoxy group, and an oxo group (═O).

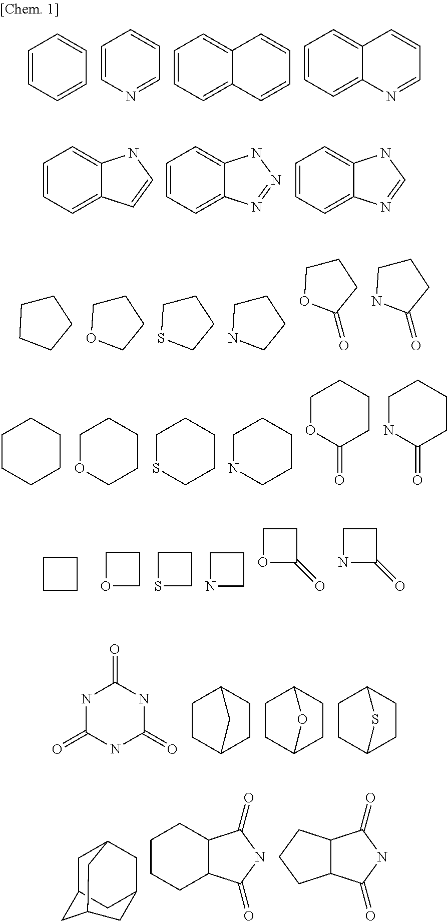

Examples of the organopolysiloxane residue constituting the branch point P¹ include the following groups, provided that R²⁵ in formulae below is a hydrogen atom, an alkyl group, an alkoxy group, or a phenyl group. The number of carbon atoms in the alkyl group and the alkoxy group of R²⁵ is preferably 1 to 10, and more preferably 1.

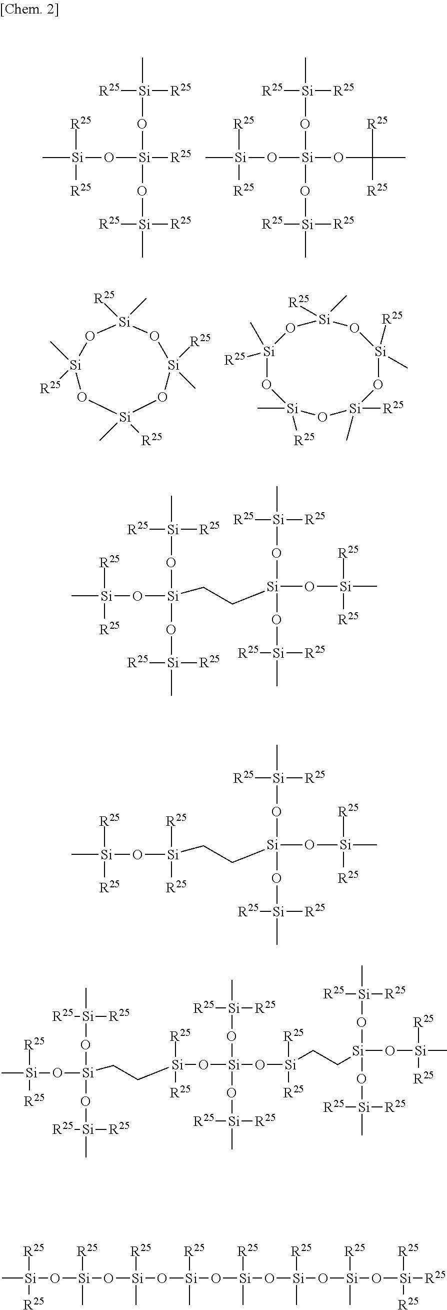

The divalent or higher-valent L¹ may have at least one bond (hereinafter referred to as “bond B¹”) selected from the group consisting of —C(O)N(R²⁶)—, —N(R²⁶)C(O)—, —C(O)O—, —OC(O)—, —C(O)—, —O—, —N(R²⁶)—, —S—, —OC(O)O—, —NHC(O)O—, —OC(O)NH—, —NHC(O)N(R²⁶)—, —SO₂N(R²⁶)—, —N(R²⁶) SO₂—, —Si(R²⁶)₂—, —OSi(R²⁶)₂—, —Si(CH₃)₂-Ph-Si(CH₃)₂—, and a divalent organopolysiloxane residue.

However, R²⁶ is a hydrogen atom, an alkyl group having 1 to 6 carbon atoms, or a phenyl group; and Ph is a phenylene group. The number of carbon atoms in the alkyl group of R²⁶ is preferably 1 to 6, more preferably 1 to 3, and even more preferably 1 or 2 from the viewpoint of easy production of the fluorine-containing ether compound.

Examples of the divalent organopolysiloxane residue include groups below, provided that R²⁷ in formulae below is a hydrogen atom, an alkyl group, an alkoxy group, or a phenyl group. The number of carbon atoms in the alkyl group and the alkoxy group of R²⁷ is preferably 1 to 10, and more preferably 1.

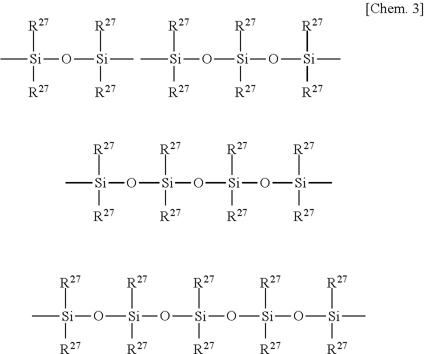

The bond B¹ is preferably at least one bond selected from the group consisting of —C(O)NR²⁶—, —N(R²⁶)C(O)—, —C(O)—, and —NR 26—from the viewpoint of easy production of the fluorine-containing ether compound, and is more preferably —C(O)NR²⁶—, —N(R²⁶)C(O)—, or —C(O)—from the viewpoint of further excellent light resistance and chemical resistance of the surface layer.

In the divalent L¹, atoms bonded to R¹ and R¹¹ are each independently N, O, S, or Si, or a carbon atom having an oxo group (═O). In other words, the atoms adjacent to R¹ and R¹¹ are each a constituent element of the bond B¹. Specific examples of the divalent L¹ include a single bond, one or more bonds B¹ (e.g., *—B¹—**, *—B¹. R²⁸—B¹—**), where R²⁸ is a single bond or a divalent organic group; *is a bonding hand on the R¹ side; and ** is a bonding hand on the R¹¹ side.

In the trivalent or higher-valent L¹, atoms bonded to R¹ and R¹¹ are each independently N, O, S, or Si, a carbon atom constituting a branch point, or a carbon atom having an oxo group (═O). In other words, the atoms adjacent to R¹ and R¹¹ are each a constituent element of the bond B¹ or branch point P¹. Specific examples of the trivalent or higher-valent L¹ include one or more branch points P¹ (e.g., {(*—)ⱼP¹(—**)_{×1}}, {(*—)ⱼP¹-R²⁸-P¹(—**)_{×1}}), and a combination of one or more branch points P¹ and one or more bonds B¹(e.g., {*—B¹-R²⁸-P¹ (—**)ₓ₁}, {*—B¹—R²⁸-P¹(—R²⁸—B¹—**)_{×1}}), where R²⁸ is a single bond or a divalent organic group; *is a bonding hand on the R¹ side; and ** is a bonding hand on the R¹¹ side.

Examples of the divalent organic group in R²⁸ include a hydrocarbon group such as a divalent aliphatic hydrocarbon group (an alkylene group, a cycloalkylene group, etc.) and a divalent aromatic hydrocarbon group (a phenylene group, etc.), and the divalent organic group may have a bond B¹ between carbon-carbon atoms of the hydrocarbon group. The number of carbon atoms in the divalent organic group is preferably 1 to 10, more preferably 1 to 6, and even more preferably 1 to 4.

L¹ is preferably a group represented by any one of formulae (L1) to (L7) below from the viewpoint of easy production of the fluorine-containing ether compound.

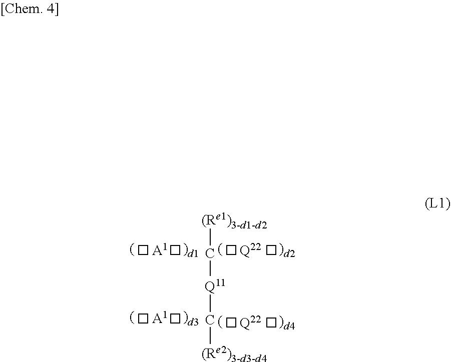

(-A¹-)_{d5}C(R^{e2})_{4-d5-d6}(-Q²²-)_{d6} (L2)

(-A²-)_{d7}N(-Q²³-)_{3-d7} (L3)

(-A³-)_{d8}Z¹(-Q²⁴-)_{d9} (L4)

(-A²-)_{d10}Si(R^{e3})_{4-d10-d11}(-Q²⁵-)_{d11} (L5)

A¹-Q²⁶ (L6)

-A¹-CH(-Q²²-)-Si(R^{e3})_{3-d12}(-Q²⁵-)_{d12} (L7)

However, in formulae (L1) to (L7), the A¹, A², or A³ side is connected to R¹ in formula (A1), and the Q²², Q²³, Q²⁴, Q²⁵, or Q²⁶ side is connected to R¹¹.

Here, A¹ is a single bond, —B³—, —B³—R³⁰—, or —B³—R³⁰—B²—, in which R³⁰ is an alkylene group or a group having —C(O)NR^{e6}—, —C(O)—, —NR^{e6}—, or —O— between carbon-carbon atoms of an alkylene group having two or more carbon atoms, and B² is —C(O)NR^{e6}—, —C(O)—, —NR^{e6}—, or —O—; B³ is —C(O)NR^{e6}—, —C(O)—, or —NR^{e6}—;
A² is a single bond or —B³—R³⁰—;
A³ is A¹ when the atom in Z¹ to which A³ is bonded is a carbon atom, and is A² when the atom in Z¹ to which A³ is bonded is a nitrogen atom;
Q¹¹ is a single bond, —O—, an alkylene group, or a group having —C(O)NR^{e6}—, —C(O)—, —NR^{e6}—, or —O— between carbon-carbon atoms of an alkylene group having two or more carbon atoms;
Q²² is a single bond, —B³—, —R³⁰—B³—, or —B²—R³⁰—B³—;
Q²³ is a single bond or —R³⁰—B³—;
Q²⁴ is Q²² when the atom in Z¹ to which Q²⁴ is bonded is a carbon atom, and is Q²³ when the atom in Z¹ to which Q²⁴ is bonded is a nitrogen atom;
Q²⁵ is a single bond or —R³⁰—B³—;
Q²⁶ is a single bond or —R³⁰—B³—;
Z¹ is a group having an (d8+d9)-valent cyclic structure with a carbon atom or nitrogen atom to which A³ is directly bonded and a carbon atom or nitrogen atom to which Q²⁴ is directly bonded;
R^{e1} is a hydrogen atom or an alkyl group;
R^{e2} is a hydrogen atom, a hydroxy group, an alkyl group, or an acyloxy group;
R^{e3} is an alkyl group;
R^{e6} is a hydrogen atom, an alkyl group having 1 to 6 carbon atoms, or a phenyl group;
d1 is an integer of 0 to 3, d2 is an integer of 0 to 3, and d1+d2 is an integer of 1 to 3;
d3 is an integer of 0 to 3, d4 is an integer of 0 to 3, and d3+d4 is an integer of 1 to 3;
d1+d3 is an integer of 1 to 5;
d2+d4 is an integer of 1 to 5;
d5 is an integer of 1 to 3, d6 is an integer of 1 to 3, and d5+d6 is an integer of 2 to 4;
d7 is 1 or 2;
d8 is an integer of 1 or more;
d9 is an integer of 1 or more;
d10 is an integer of 1 to 3, d11 is an integer of 1 to 3, and d10+d11 is an integer of 2 to 4; and
d12 is an integer of 1 to 3.

Note that when there is a plurality of A¹, the plurality of A¹ is the same as or different from each other. A², A³. Q²², Q²³, Q²⁴, Q²⁵, R^{e1}, R^{e2}, and R^{e3} are also the same.

In addition, d1+d3, d5, d7, d8, and d10 are j, and d2+d4, d6, 3-d7, d9, d11, 1+d12 are x 1.

The number of carbon atoms in the alkylene group of R³⁰ is preferably 1 to 10, more preferably 1 to 6, and even more preferably 1 to 4 from the viewpoint of easy production of the fluorine-containing ether compound and further excellent friction durability, light resistance, and chemical resistance of the surface layer, provided that the lower limit value of the number of carbon atoms in the alkylene group is 2 when it has a specific bond between carbon-carbon atoms.

The cyclic structure in Z¹ include the cyclic structure described above, and the preferred embodiments are also the same.

The number of carbon atoms in the alkyl group of R^{e1}, R^{e2}, or R^{e3} is preferably 1 to 6, more preferably 1 to 3, and even more preferably 1 or 2 from the viewpoint of easy production of the fluorine-containing ether compound.

The number of carbon atoms in the alkyl group moiety in the acyloxy group of R^{e2} is preferably 1 to 6, more preferably 1 to 3, and even more preferably 1 or 2 from the viewpoint of easy production of compound 1.

d9 is preferably 2 to 6, more preferably 2 to 4, and even more preferably 2 or 3 from the viewpoint of easy production of the fluorine-containing ether compound and further excellent friction durability and fingerprint stain removability of the surface layer.

Another embodiment of L¹ includes a group represented by any one of formulae (L11) to (L17) below.

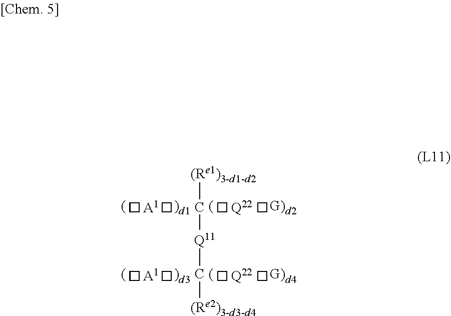

(-A¹-)_{d5}C(R^{e2})_{4-d5-d6}(-Q²²-G)_{d6} (L12)

(-A²-)_{d7}N(-Q²³-G)_{3-d7} (L¹³)

(-A³-)_{d8}Z¹(-Q²⁴_G)_{d9} (L¹⁴)

(-A²-)_{d10}Si(R^{e3})_{4-d10-d11}(-Q²⁵-G)_{d11} (L15)

-A¹-Q²⁶-G (L16)

-A¹-CH(-Q²²-)-Si(R^{e3})_{3-d12}(-Q²⁵-G)_{d12} (L17)

However, in formulae (L11) to (L17), the A¹, A², or A³ side is connected to R¹ in formula (A1), and the Q²², Q²³, Q²⁴, Q²⁵, or Q²⁶ side is connected to R¹¹. G is of the following formula (G21), and two or more Gs contained in L¹ are optionally the same or different. The symbols other than G are the same as the symbols in formulae (L11) to (L17).

—Si(R²¹)₃₋ₖ(-Q³-)ₖ (G21)

However, in formula (G21), the Si side is connected to Q²², Q²³, Q²⁴, Q²⁵, or Q²⁶, and the Q³ side is connected to R¹¹. R²¹ is an alkyl group. Q³ is a single bond or —R³¹—B³—, in which R³¹ is an alkylene group, a group having —C(O)NR³²—, —C(O)—, —NR³²— or —O— between carbon-carbon atoms of an alkylene group having two or more carbon atoms, or —(OSi(R²²)₂)ₚ₁₁—O—, and two or more Q³s are optionally the same or different. k is 2 or 3. R³² is a hydrogen atom, an alkyl group having 1 to 6 carbon atoms, or a phenyl group. R²² is an alkyl group, a phenyl group, or an alkoxy group, and two R²²s are optionally the same or different. p11 is an integer of 0 to 5, and when p11 is two or more, two or more (OSi(R²²)₂)s are optionally the same or different.

The number of carbon atoms in the alkylene group of Q³ is preferably 1 to 10, more preferably 1 to 6, and even more preferably 1 to 4 from the viewpoint of easy production of the fluorine-containing ether compound and further excellent friction durability, light resistance, and chemical resistance of the surface layer, provided that the lower limit value of the number of carbon atoms in the alkylene group is 2 when it has a specific bond between carbon-carbon atoms.

The number of carbon atoms in the alkyl group of R²¹ is preferably 1 to 6, more preferably 1 to 3, and even more preferably 1 or 2 from the viewpoint of easy production of the fluorine-containing ether compound.

The number of carbon atoms in the alkyl group of R²² is preferably 1 to 6, more preferably 1 to 3, and even more preferably 1 or 2 from the viewpoint of easy production of the fluorine-containing ether compound.

The number of carbon atoms in the alkoxy group of R²² is preferably 1 to 6, more preferably 1 to 3, and even more preferably 1 or 2 from the viewpoint of excellent storage stability of the fluorine-containing ether compound.
p11 is preferably 0 or 1.

Examples of the compound (A1) include the following, where R^{f} is [R^{f1}—(OR^{f11})_{yl}—O—R¹].

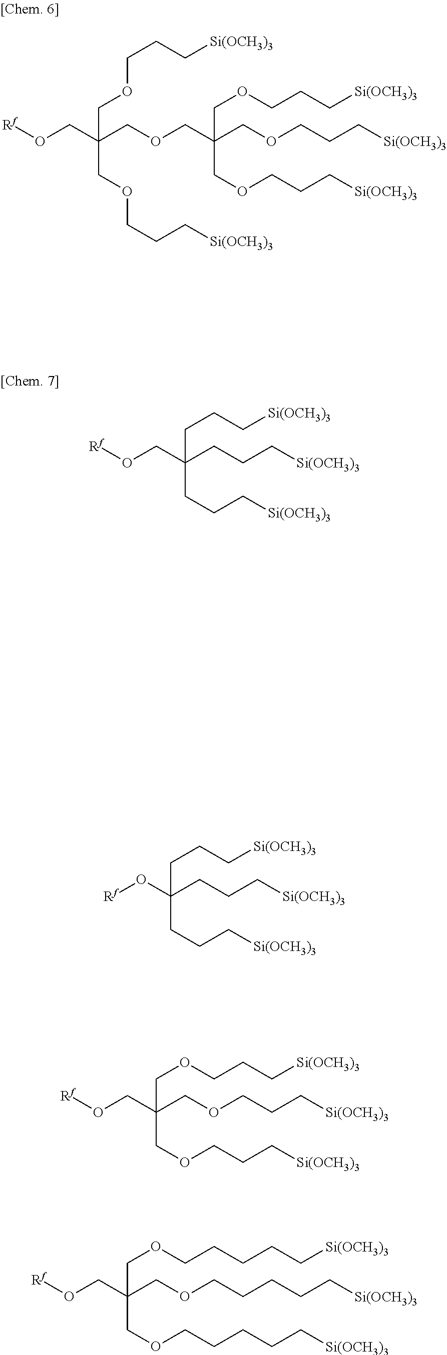

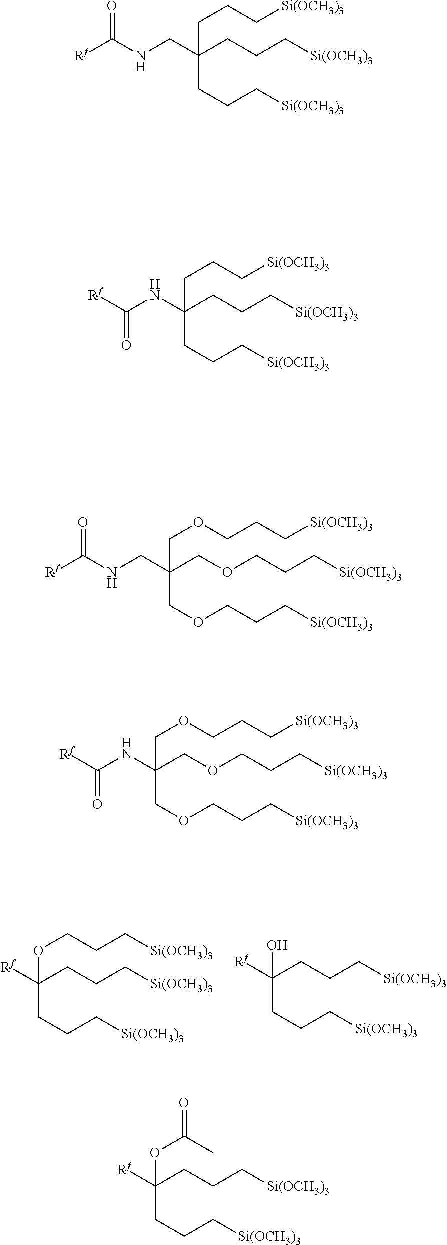

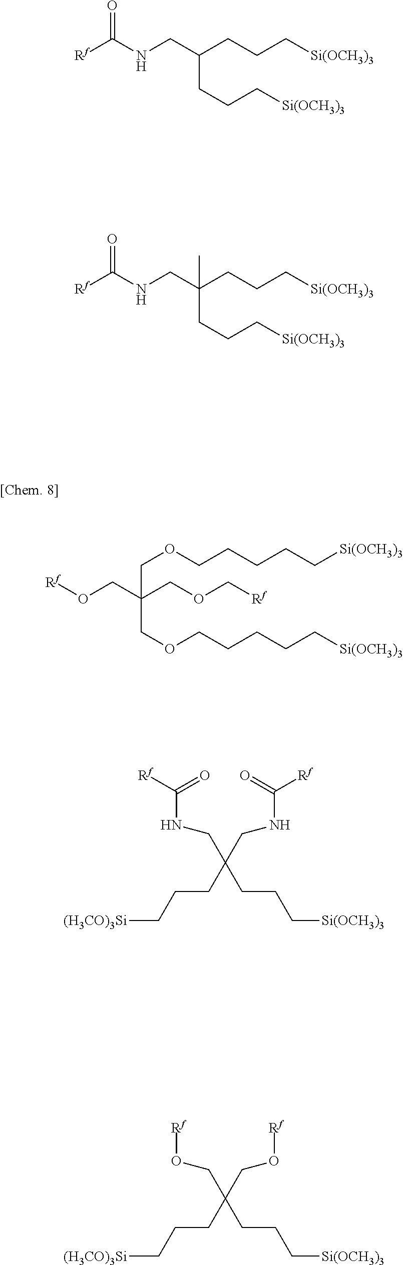

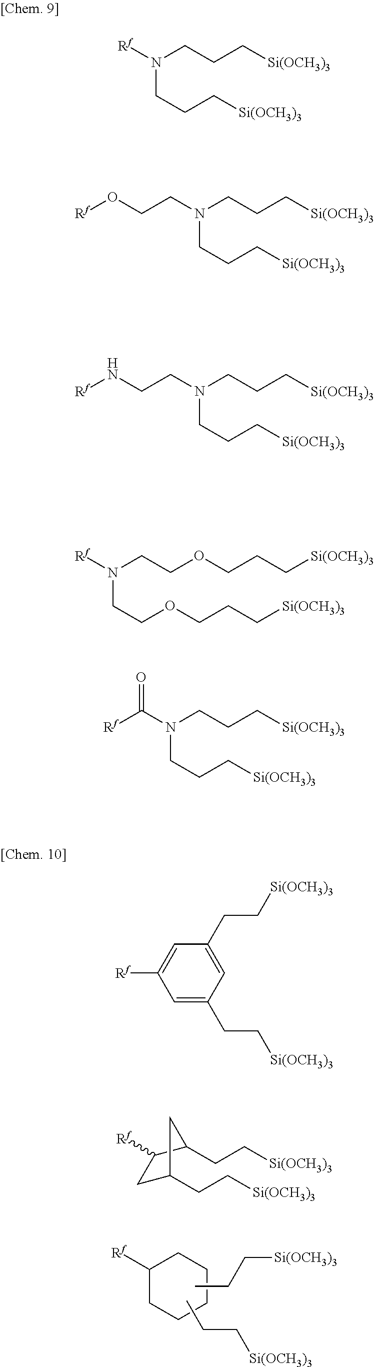

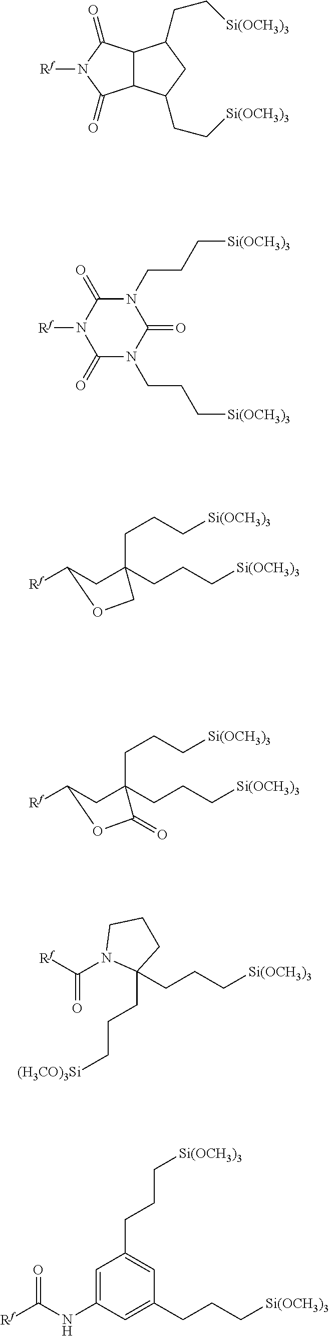

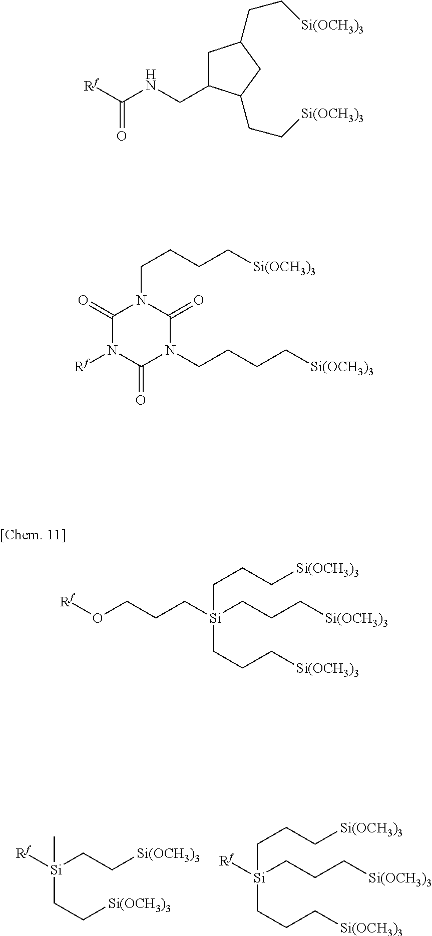

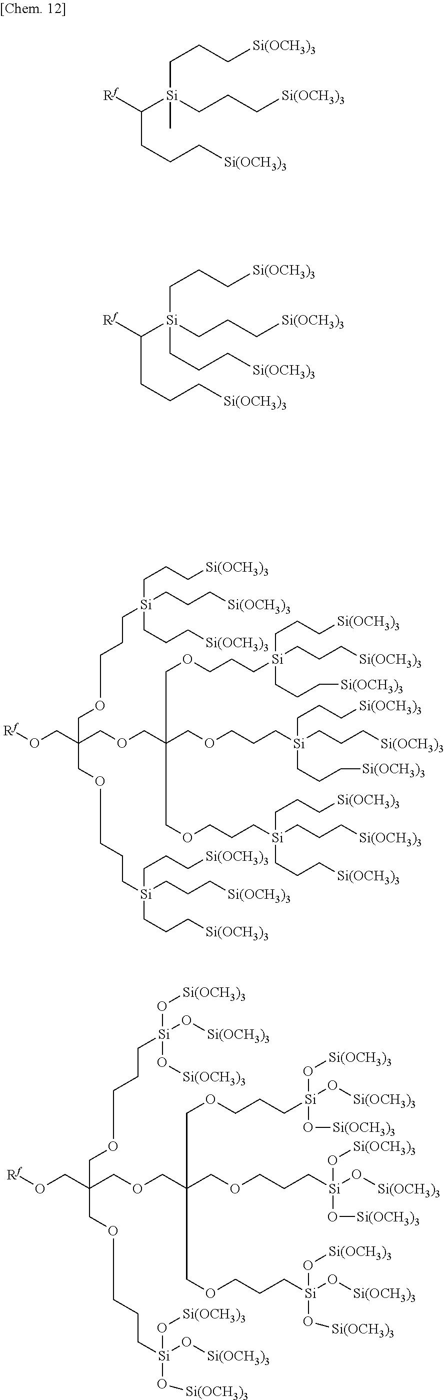

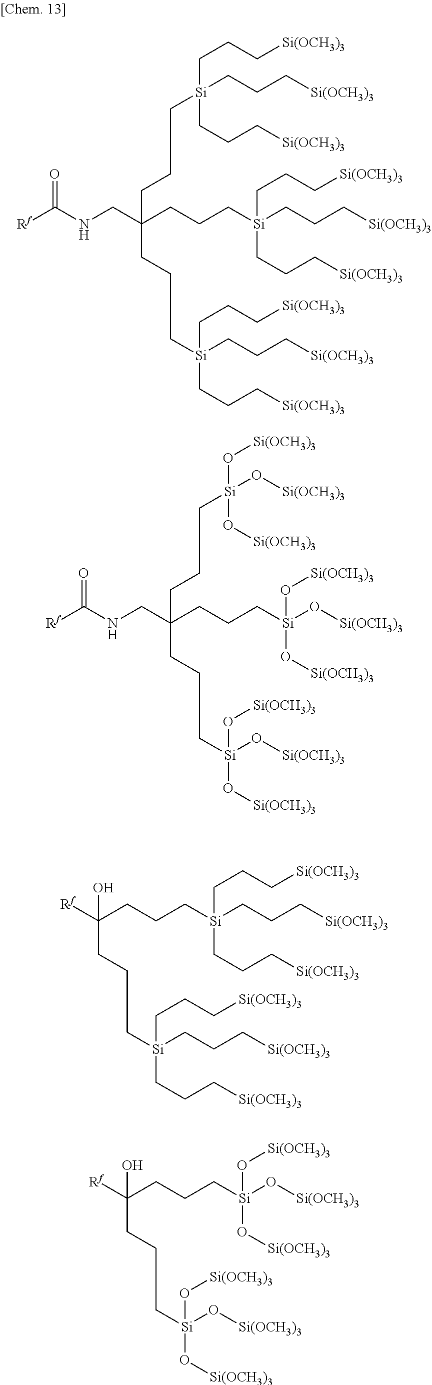

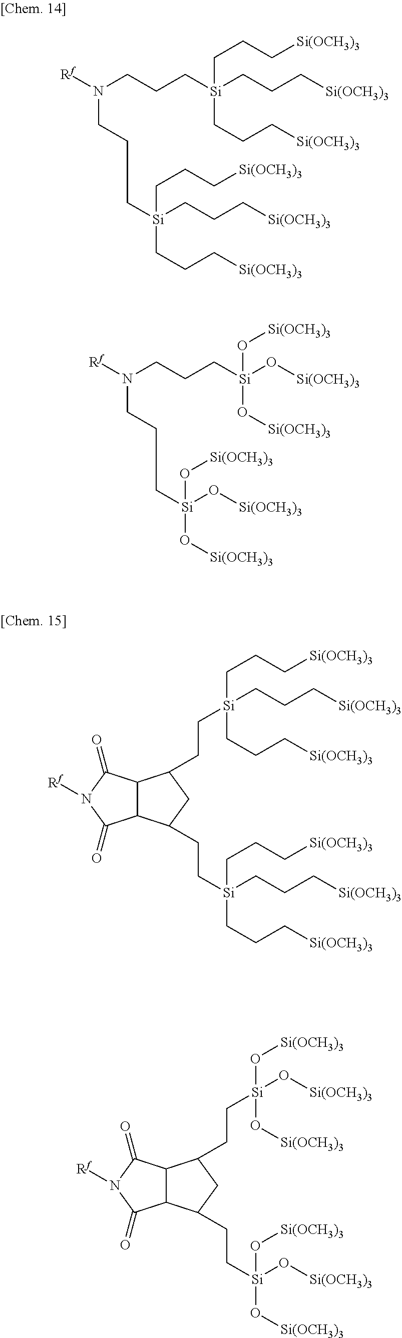

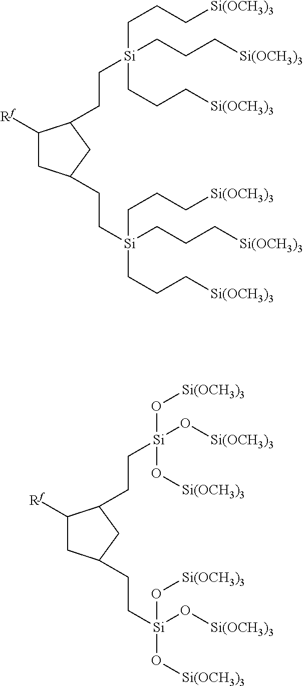

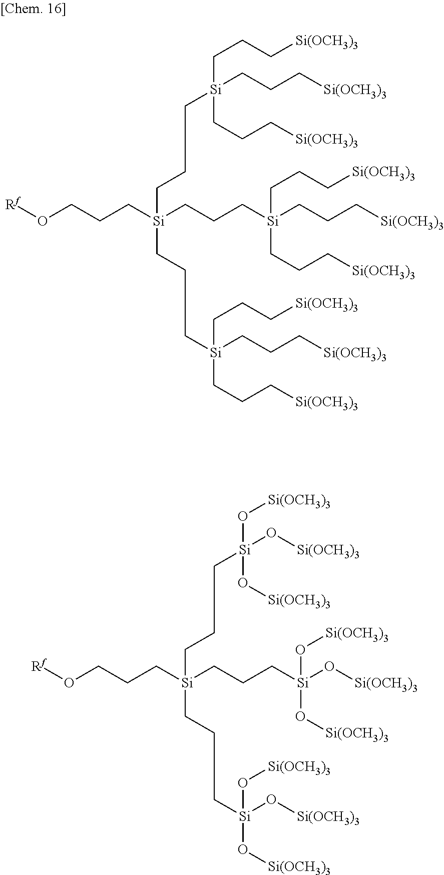

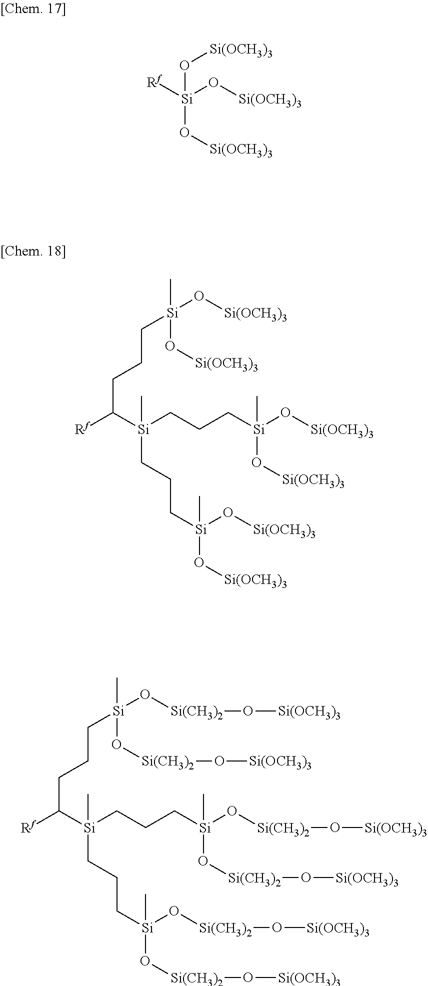

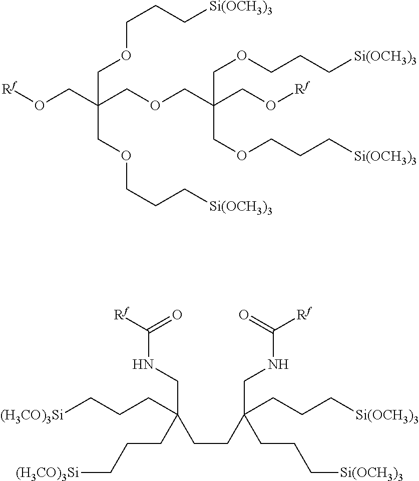

### (Compound (A2))

Compound (A2) has a structure represented by formula (A2):

(T³¹-R³¹)ₓ₃-L³-R³—(OR^{f12})_{y2}—O—R²-L²-(R²¹-T²¹)ₓ₂ (A2)

where each symbol in formula (A2) is as described above.

R^{f12} and (OR^{f12})_{y2} are the same as R^{f11} and (OR^{f11})_{y1}, and preferred aspects are also the same.

R² and R³ are each independently the same as R¹, and preferred aspects are also the same.

R²¹ and R³¹ are the same as R¹¹, and preferred aspects are also the same. However, “bonded to L¹” is replaced with “bonded to L²” in the case of R²¹ and is replaced with “bonded to L³” in the case of R³¹ Furthermore, “bonded to T¹¹” is replaced with “bonded to T²¹” in the case of R²¹ and “bonded to T³¹” in the case of R³¹. When L² is a single bond, R²¹ is directly bonded to R². When L³ is a single bond, R³¹ is directly bonded to R³.

T²¹ and T³¹ are each independently —SiR^{a21}_{z21}R^{a22}_{3-z21}, R^{a21}, R^{a22}, z21 are the same as R^{a1}, R^{a2}, and z1 constituting the group (g1), respectively, and preferred aspects are also the same.

x2 and x3 are each independently the same as x1, and preferred aspects are also the same.

L² and L³ are each independently the same as L¹ where j is 1.

For example, when L² and L³ are each a single bond, compound (A2) is represented by formula (A2′):

T³¹-R³¹—R³—(OR^{f12})_{y2}—O—R²-L²-R²¹-T²¹ (A2′)

where each symbol in formula (A2′) is the same as in formula (A2).

When L² or L³ is a trivalent or higher-valent group, L² or L³ has at least one branch point selected from the group consisting of C, N, Si, a cyclic structure, and a (1+x2) valent or (1+x3) valent organopolysiloxane residue (hereinafter referred to as “branch point p²”).

When N is a branch point P², the branch point P² is represented by, for example, *—N(—**)₂, where * is a bonding hand on the R² or R³ side; and ** is a bonding hand on the R²¹ or R³¹ side.

When Cis the branch point P², the branch point P² is represented by, for example, *—C(—**)₃ or *—CR²⁹ (—**)₂, where * is a bonding hand on the R² or R³ side; ** is a bonding hand on the R²¹ or R³¹ side; and R²⁹ is a monovalent group, for example, a hydrogen atom, a hydroxy group, an alkyl group, and an alkoxy group.

When Si is the branch point P², the branch point P² is represented by, for example, *—Si(—**)₃ or *—SiR²⁹ (—**)₂, where * is a bonding hand on the R² or R³ side; ** is a bonding hand on the R²¹ or R³¹ side; and R²⁹ is a monovalent group, for example, a hydrogen atom, a hydroxy group, an alkyl group, and an alkoxy group.

The cyclic structure and the organopolysiloxane residue constituting the branch point P² are the same as those of the branch point P¹, and preferred aspects are also the same.

The divalent or higher-valent L² or L³ may each independently have the bond B¹. Aspects of the bond B¹ are as described above, and preferred aspects are also the same.

In the divalent L² or L³, atoms bonded to R² and R²¹ or R³ and R³¹ are each independently N, O, S, or Si, or a carbon atom having an oxo group (═O). In other words, the atoms adjacent to R² and R²¹ or R³ and R³¹ are each a constituent element of the bond B¹. Specific examples of the divalent L² or L³ include a single bond, one or more bonds B¹ (e.g., *—B¹—**, *—B¹—R²⁸—B¹—**), where R²⁸ is a single bond or a divalent organic group; * is a bonding hand on the R² or R³ side; and ** is a bonding hand on the R²¹ or R³¹ side.

In the trivalent or higher-valent L² or L³, atoms bonded to R² and R²¹ or R³ and R³¹ are each independently N, O, S, or Si, a carbon atom constituting a branch point, or a carbon atom having an oxo group (═O). In other words, the atoms adjacent to R² and R²¹ or R³ and R³¹ are each a constituent element of the bond B¹ or the branch point P². Specific examples of the trivalent or higher-valent L² or L³ include one or more branch points P² (e.g., {*—P²(—**)ₓ { }, {*—P²—R²⁸—P²(—**)^{x}{ }), and a combination of one or more branch points P² and one or more bonds B¹ (e.g., {*—B¹—R²⁸—P²(—**)ₓ}}, {*—B¹—R²⁸—P²(—R²⁸—B¹—**)ₓ}}), where x is x2 in the case of L² and x3 in the case of L³. R²⁸ is a single bond or a divalent organic group; * is a bonding hand on the R² or R³ side; and ** is a bonding hand on the R²¹ or R³¹ side.

Aspects of R²⁸ are as described above, and preferred aspects are also the same.

Preferably, L² or L³ are each independently a group represented by any one of formulae (L21) to (L27) below from the viewpoint of easy production of the fluorine-containing ether compound.

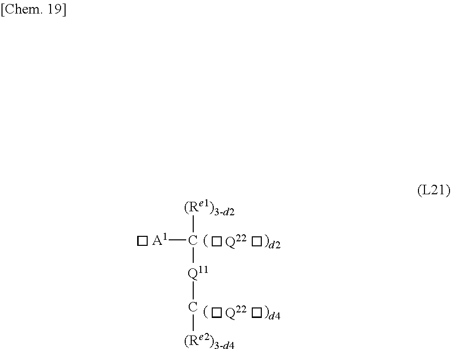

-A¹-C(R^{e2})_{4-d6}(-Q²²-)_{d6} (L22)

-A²-N(-Q²³-)₂ (L23)

-A³-Z¹(-Q²⁴-)_{d9} (L24)

-A²-Si(R^{e3})_{4-d11}(-Q²⁵-)_{d11} (L25)

A¹-Q²⁶ (L26)

-A¹-CH(-Q²²-)-Si(R^{e3})_{3-d12}(-Q²⁵-)_{d12} (L27)

However, in formulae (L21) to (L27), the A¹, A², or A³ side is connected to R² or R³, and the Q²², Q²³, Q²⁴, Q²⁵, or Q²⁶ side is connected to R²¹ or R³¹.

Here, A¹, A², A³, Q¹¹, Q²², Q²³, Q²⁴, Q²⁵, Q²⁶, R^{e1}, R^{e2}, R^{e3}, and R^{e6} are the same as those described in L¹ above, and preferred aspects are also the same.

Z¹ is a group having an (1+d9)-valent cyclic structure with a carbon atom or nitrogen atom to which A³ is directly bonded and a carbon atom or nitrogen atom to which Q²⁴ is directly bonded;

d2 is an integer of 0 to 3, d4 is an integer of 0 to 3, and d2+d4 is an integer of 1 to 5;

d6 is an integer of 1 to 3;

d9 is an integer of 1 or more;

d11 is an integer of 1 to 3; and

d12 is an integer of 1 to 3.

Note that d2+d4, d6, d9, d11, and 1+d12 are each x2 or x3.

d9 is preferably 2 to 6, more preferably 2 to 4, and even more preferably 2 or 3 from the viewpoint of easy production of the fluorine-containing ether compound and further excellent friction durability and fingerprint stain removability of the surface layer.

Another embodiment of L² or L³ includes a group represented by any one of formulae (L31) to (L37) below.

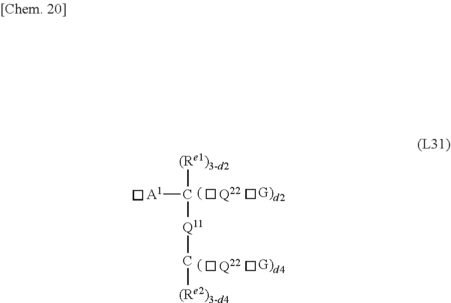

-A¹-C(R^{e2})_{4-d6}(-Q²²-G)_{d6} (L32)

-A²-N(-Q²³-G)₂ (L33)

-A³-Z¹(-Q²⁴-G)_{d9} (L34)

-A²Si(R^{e3})_{4-d11}(-Q²⁵-G)_{d11} (L35)

-A¹-Q²⁶-G (L36)

-A¹-CH(-Q²²-)-Si(R^{e3})_{3-d12}(-Q²⁵-G)_{d12} (L37)

However, in formulae (L31) to (L37), the A¹, A², or A³ side is connected to R² or R³, and the Q²², Q²³, Q²⁴, Q²⁵, or Q²⁶ side is connected to R²¹ or R³¹. G is the same as the group (G21), and preferred aspects are also the same. The symbols other than G are the same as the symbols in formulae (L²¹) to (L²⁷), and preferred aspects are also the same.

Examples of the compound (A²) include the following, where Q^{f} is —R³—(OR^{f12})_{y2}—O—R²—.

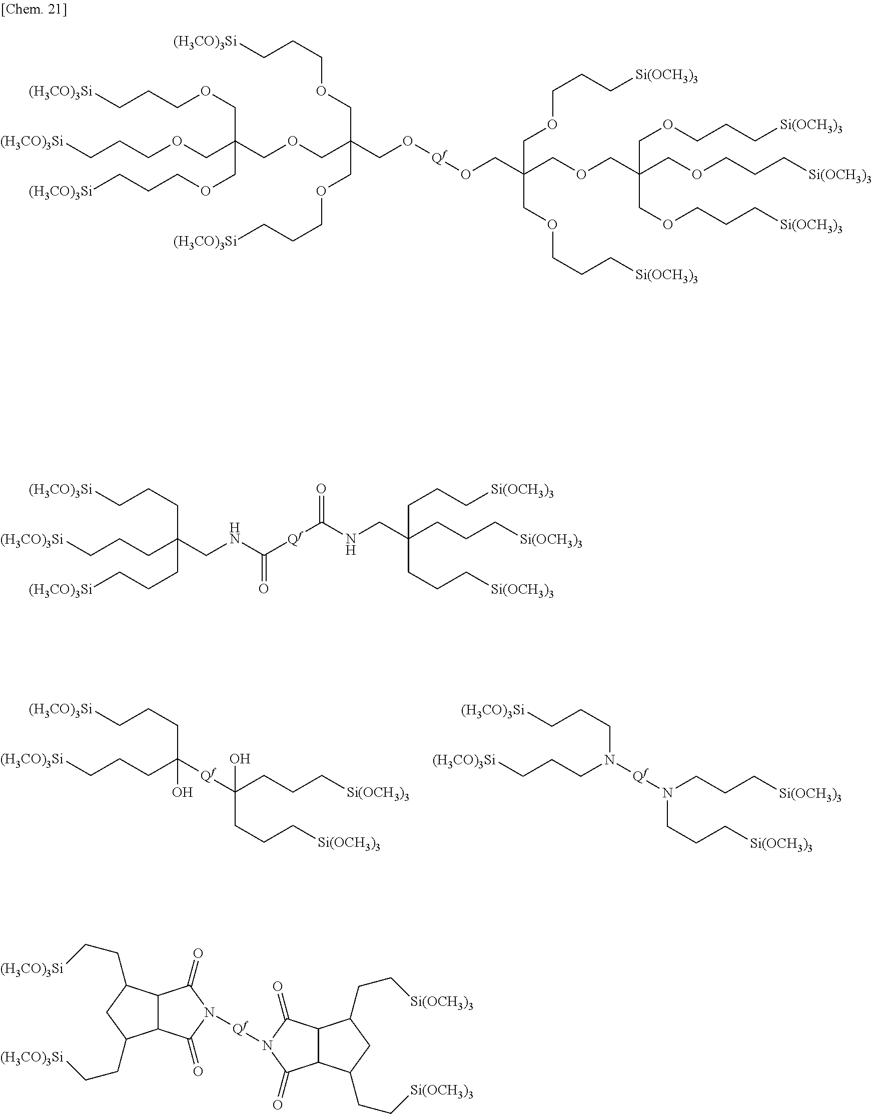

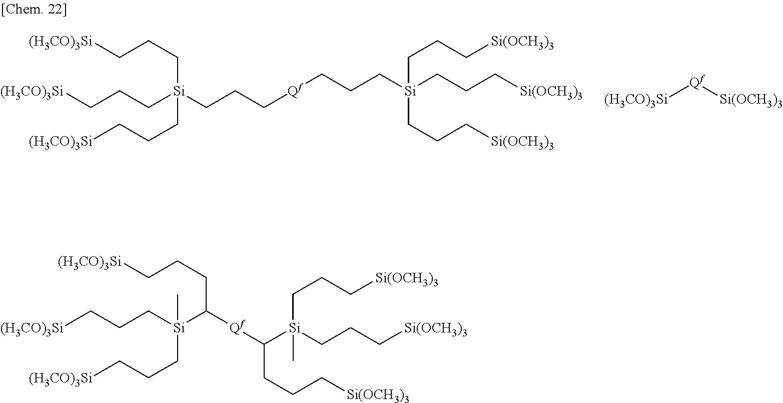

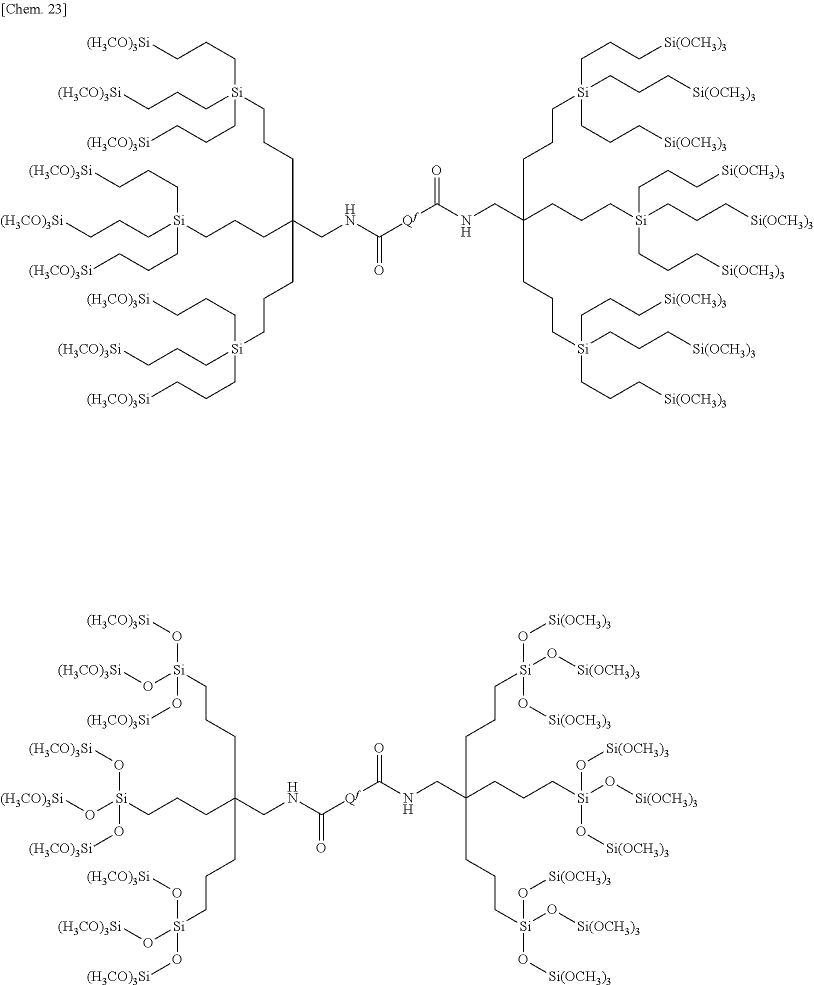

### (Compound (A³))

Compound (A³) has a structure represented by formula (A³):

Q¹[-(OR^{f13})_{y3}—O—R⁴-L⁴-(R⁴¹-T⁴¹)ₓ₄]ᵣ₁ (A³)

where each symbol in formula (A³) is as described above.

R^{f13} and (OR^{f13})_{y3} are the same as R^{f11} and (OR^{f11})_{y1}, and preferred aspects are also the same.

R⁴ is the same as R¹, and preferred aspects are also the same.

R⁴¹ is the same as R¹¹, and preferred aspects are also the same. However, “bonded to L′” is replaced with “bonded to L⁴”. In addition, “bonded to T¹¹” is replaced with “bonded to T⁴¹”. When L⁴ is a single bond, R⁴¹ is directly bonded to R⁴.

T⁴¹ is —SiR^{a41}_{z41}R^{a42}_{3-z41}, R^{a41}, R^{a42}, z41 are the same as R^{a1}, R^{a2}, and z1 constituting the group (g1), respectively, and preferred aspects are also the same.

x4 is the same as x1, and preferred aspects are also the same.

L⁴ is the same as L² or L³, and preferred aspects are also the same.

Q¹ is an r1 valent group having a branch point, where r1 is 3 or 4.

Examples of the branch point P³ constituting Q¹ include N, C, Si, and a cyclic structure. The number of branch points P³ may be one or may be two or more.

When N is a branch point P³, the branch point P³ is represented by, for example, N(—*)₃ or NR²⁹ (—*)₂.

When Cis the branch point P³, examples of the branch point p³ include C(—*)₄, CR²⁹(—*)₃, and C(R²⁹)₂(—*)_{2.} When Si is the branch point P³, examples of the branch point P³ include Si(—*)₄, SiR²⁹(—*)₃, and Si(R²⁹)₂(—*)₂, where * is a bonding hand on the OR^{f13} side, and R²⁹ is a monovalent group. Examples of R²⁹ include a hydrogen atom, a fluorine atom, a hydroxy group, an alkyl group, a fluoroalkyl group, and a fluoropolyether chain having no R⁴¹-T⁴¹.

The cyclic structure constituting the branch point P³ is the same as that of the branch point P¹, and may further have, as substituents of the cyclic structure, a fluorine atom, a fluoroalkyl group, and a fluoropolyether chain having no R⁴¹-T⁴¹, in addition to the substituents described above.

Q¹ is preferably a group represented by any one of formulae (Q1) to (Q8) below from the viewpoint of easy production of the fluorine-containing ether compound.

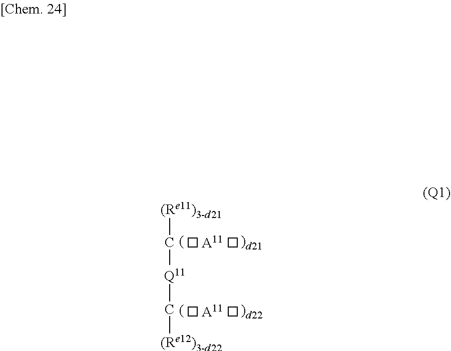

C(-A¹¹-)_{d23}(R^{e12})_{4-d23} (Q²)

N(-A¹²-)₃ (Q³)

Z¹(-A¹³-)_{d24} (Q⁴)

Si(-A¹²-)_{d25}(R^{e13})_{4-d26} (Q⁵)

CH(-A ¹¹-)₂-Si(R^{e13})_{3-d26}(-A¹¹-)_{d26} (Q⁶)

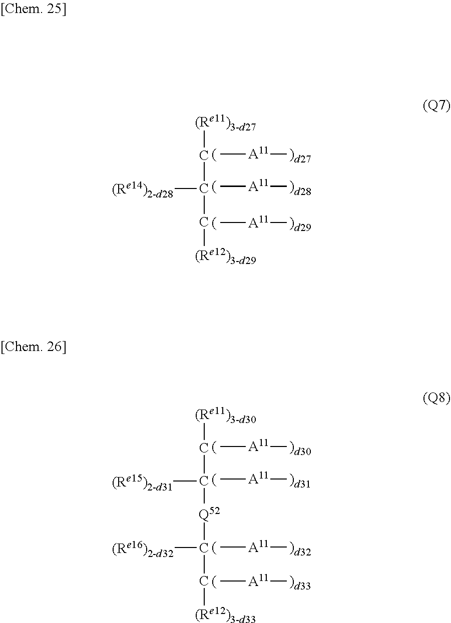

However, in formulae (Q1) to (Q8), A¹¹, A¹², or A¹³ is connected to (OR^{f13}).

Here, A¹¹ is a single bond, —R⁴⁰—, or —B¹³—R⁴⁰—, in which R⁴⁰ is an alkylene group, a fluoroalkylene group, or a group having —C(O)NR^{e17}—, —C(O)—, —NR^{e17}—, or —O— between carbon-carbon atoms of an alkylene group or fluoroalkylene group having two or more carbon atoms, and B¹³ is —C(O)NR^{e6}—, —C(O)—, —NR^{e6}—, or —O—;
A¹² is a single bond or —R⁴⁰—;
A¹³ is A¹¹ when the atom in Z¹ to which A¹³ is bonded is a carbon atom, and is A¹² when the atom in Z¹ to which A¹³ is bonded is a nitrogen atom;
Z¹ is a group having an r1-valent cyclic structure with a carbon atom or nitrogen atom to which A¹³ is directly bonded;
Q⁵² is a single bond, —O—, an alkylene group, a fluoroalkylene group, or a group having-C(O)NR^{e17}—, —C(O)—, —NR^{e17}—, or —O— between carbon-carbon atoms of an alkylene group or fluoroalkylene group having two or more carbon atoms;
R^{e11} is a hydrogen atom, a fluorine atom, an alkyl group, a fluoroalkyl group, a fluoropolyether chain having no R⁴¹-T⁴¹, or a group having a repeating structure of -Q⁵²-C(R^{e11})_{3-d21}(-A¹¹-)_{d21} within a range where r1 is 3 to 4;
R^{e12} is a hydrogen atom, a fluorine atom, a hydroxy group, an alkyl group, a fluoroalkyl group, or a fluoropolyether chain having no R⁴¹-T⁴¹;
R^{e13} is an alkyl group or a fluoroalkyl group; R^{e14}, R^{e15}, and R^{e16} are each independently a hydrogen atom, a fluorine atom, an alkyl group, or a fluoroalkyl group; R^{e17} is a hydrogen atom, an alkyl group having 1 to 6 carbon atoms, a fluoroalkyl group, or a phenyl group optionally substituted with fluorine;
d21 is an integer of 0 to 3, d22 is an integer of 0 to 3, and d21+d22 is an integer of 3 to 4;
d23 is 3 or 4;
d24 is 3 or 4;
d25 is 3 or 4;
d26 is 1 or 2;
d27 is an integer of 1 to 3;
d28 is 1 or 2;
d29 is an integer of 1 to 3;
d30 is an integer of 1 to 3;
d31 is 1 or 2;
d32 is 1 or 2; and
d33 is an integer of 1 to 3.

Note that when there is a plurality of A¹¹, the plurality of A¹¹ is the same as or different from each other. A¹², A¹³, R^{e11}, R^{e12}, and R^{e13} are also the same.

The number of carbon atoms in the alkylene group or fluoroalkylene group of R⁴⁰ is preferably 1 to 10, more preferably 1 to 6, and even more preferably 1 to 4 from the viewpoint of easy production of the fluorine-containing ether compound and further excellent friction durability, light resistance, and chemical resistance of the surface layer, provided that the lower limit value of the number of carbon atoms in the alkylene group is 2 when it has a specific bond between carbon-carbon atoms.

The cyclic structure in Z¹ include the cyclic structure described above, and the preferred embodiments are also the same.

The number of carbon atoms in the alkyl group or fluoroalkylene group of R^{e11}, R^{e12}, R^{e13}, R^{e14}, R^{e15}, and R^{e16} is preferably 1 to 6, more preferably 1 to 3, and even more preferably 1 or 2 from the viewpoint of easy production of the fluorine-containing ether compound.

Examples of the compound (A³) include the following, where R^{f3} is (OR^{f13})_{y3}—O—R⁴.

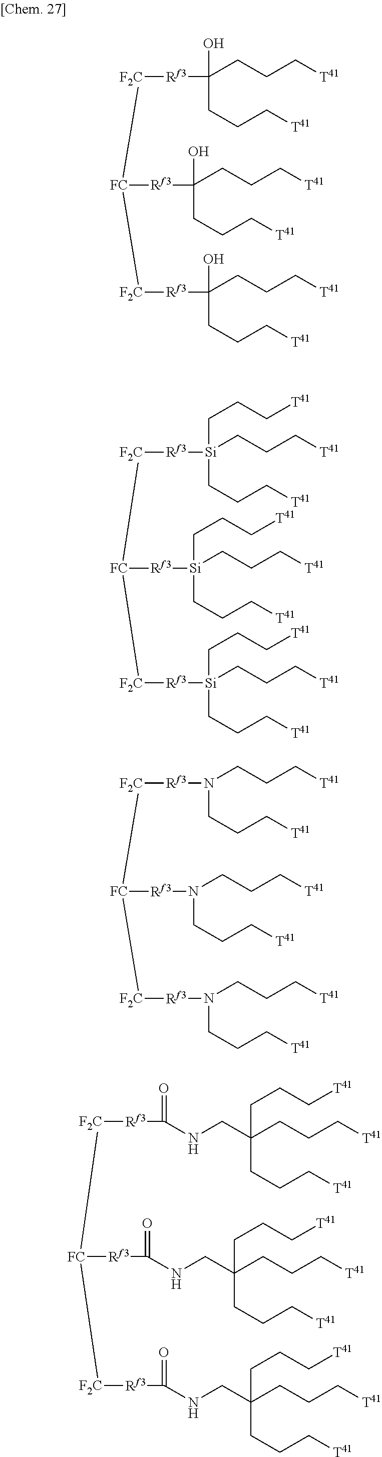

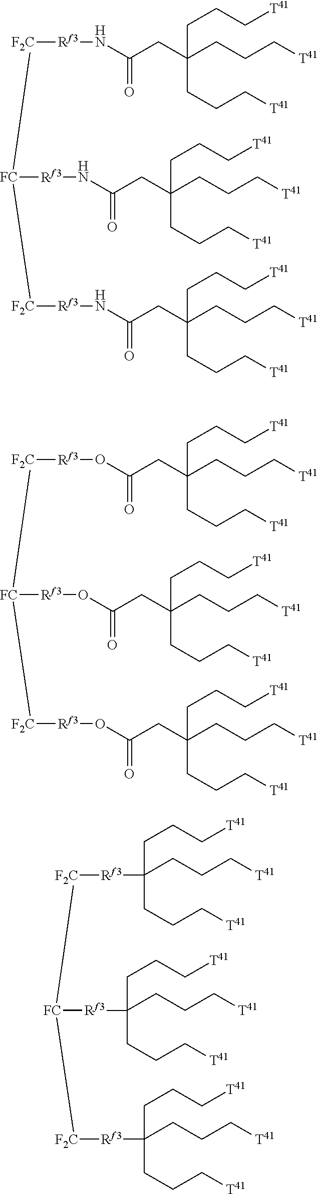

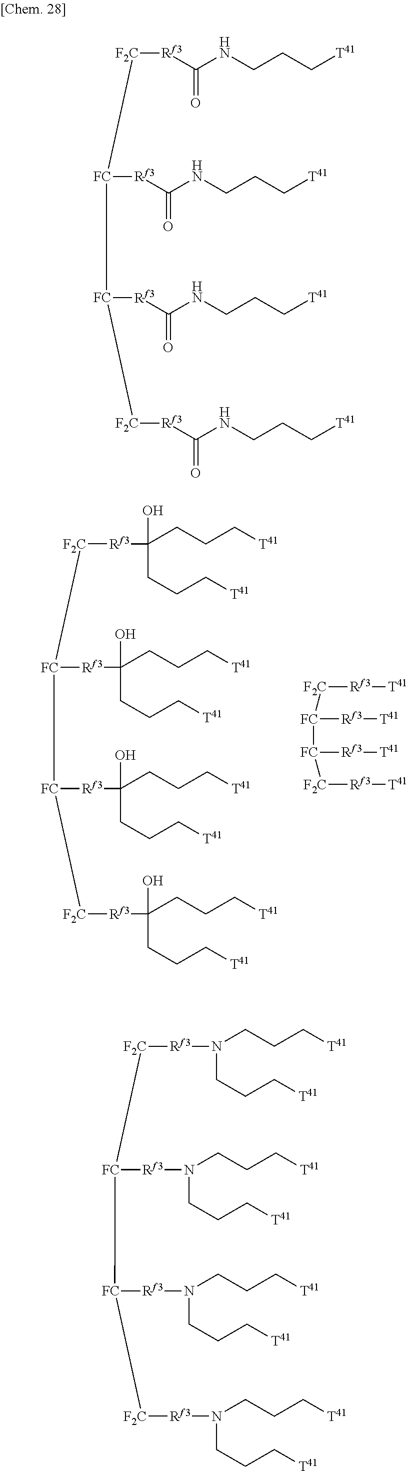

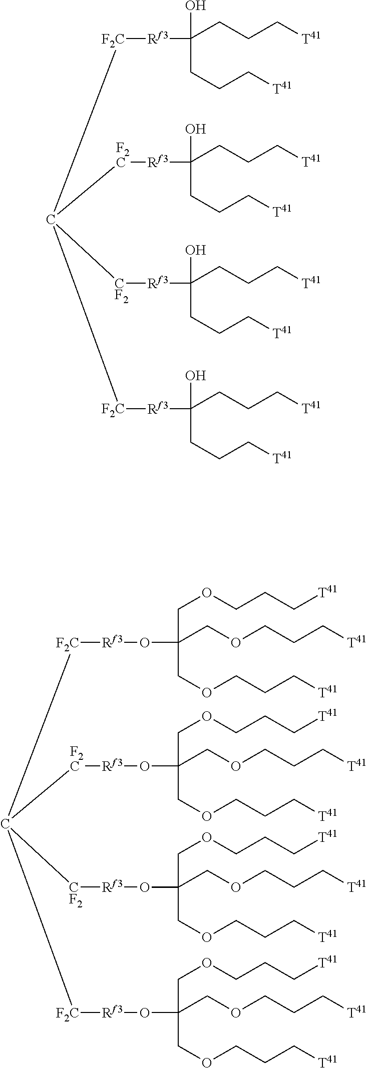

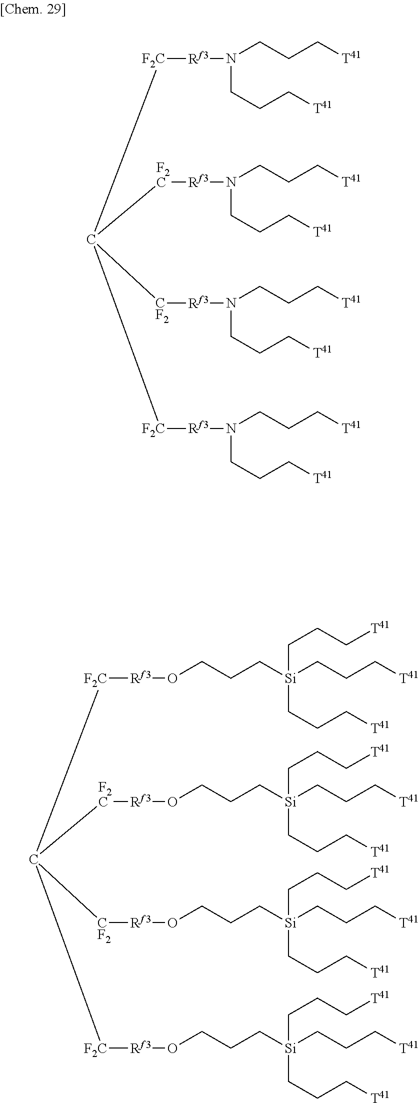

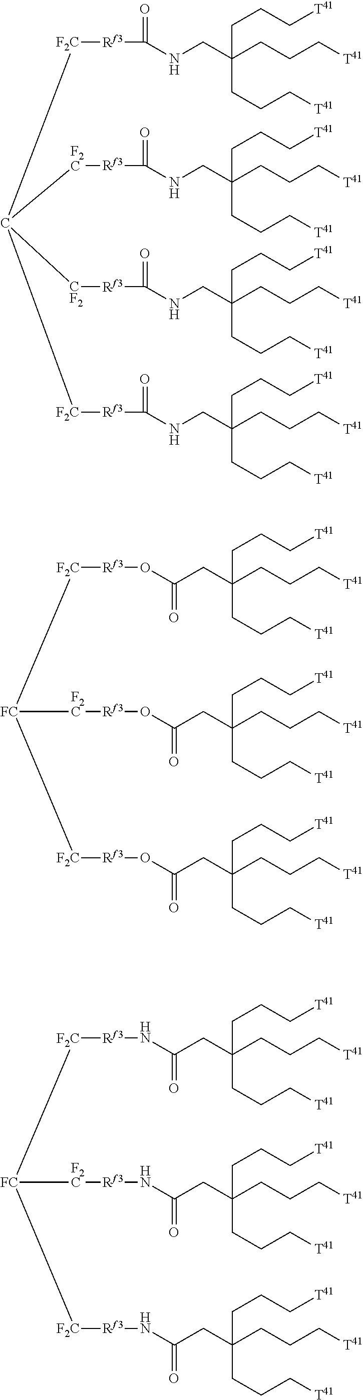

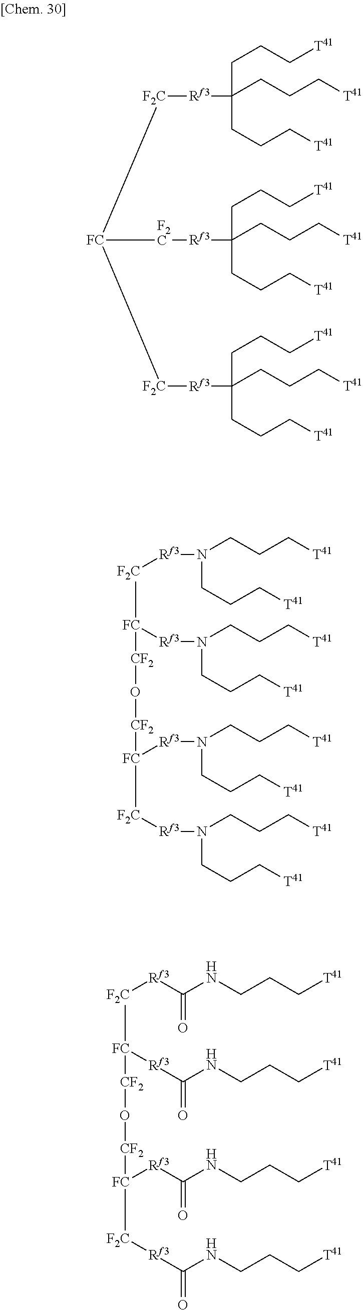

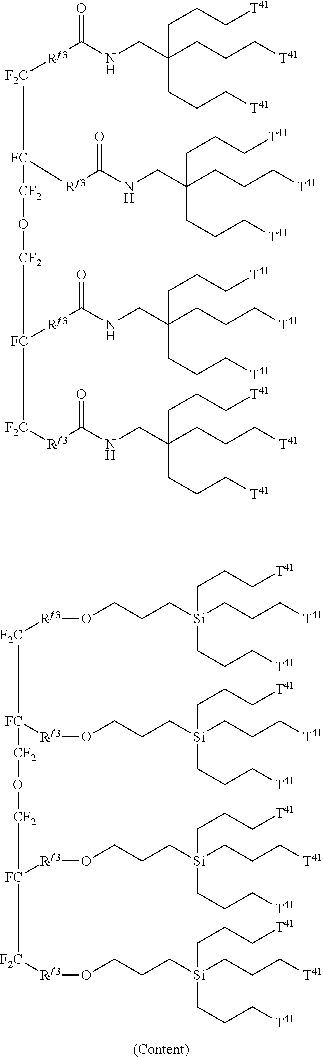

The content of the fluorine-containing ether compound is preferably 0.01 to 50% by mass, more preferably 0.03 to 40% by mass, and even more preferably 0.05 to 30% by mass with respect to the total mass of the present surface treating agent. If the content of the fluorine-containing ether compound is within the above ranges, the surface layer is more excellent in water/oil repellency, friction durability, fingerprint stain removability, lubricity, and appearance.

### <Specific Ion>

The present surface treating agent contains a specific ion. The specific ion means one or more ions selected from the group consisting of an iodide ion and a bromide ion as described above.

The present surface treating agent may contain only one of an iodide ion or a bromide ion, or may contain both of an iodide ion and a bromide ion, as the specific ion.

The content of the specific ion is 0.05 to 2.00 ppm by mass with respect to the total mass of the present surface treating agent.

The content of the specific ion is preferably 0.10 ppm by mass or more, and more preferably 0.20 ppm by mass or more, from the viewpoint of superior acid resistance of the surface layer.

The content of the specific ion is preferably 1.90 ppm by mass or less, and more preferably 1.50 ppm by mass or less, from the viewpoint of superior long-term storage stability of the present surface treating agent.

Note that the content of the specific ion means the content of only one of iodide ion or bromide ion when only one of them is contained, and means the total amount thereof when both are contained.

The content of the specific ion is preferably 0.5 to 20 ppm by mass, more preferably 1 to 19 ppm by mass, and even more preferably 2 to 15 ppm by mass with respect to the total mass of the fluorine-containing ether compound in the present surface treating agent. When the content is 2 ppm by mass or more, the surface layer is superior in acid resistance, and when the content is 15 ppm by mass or less, the present surface treating agent is superior in long-term storage stability.

The content of the specific ion contained in the present surface treating agent can be measured by ion chromatography to be described in the section of Examples later.

The content of the specific ion in the present surface treating agent may be adjusted to be within the above range by adding the specific ion itself in the production of the present surface treating agent, or may be adjusted to be within the above range by adding a metal iodide salt (e.g., potassium iodide, sodium iodide) or a metal bromide salt (e.g., potassium bromide, sodium bromide).

Alternatively, synthesis may be performed using an intermediate containing the specific ion, and the amount of the specific ion in the final product may be adjusted by varying the washing conditions.

The content of the specific ion contained in the present surface treating agent can also be adjusted to be within the above range by addition of a solution obtained by mixing an aqueous hydroiodic acid solution or an aqueous hydrobromic acid solution with a fluorine-based organic solvent (e.g., C₄F₉OC₂H₅ (manufactured by 3M, Novec (registered trademark) 7200)) and then removing water (i.e., a solution containing the specific ion and the fluorine-based organic solvent) in the production of the present surface treating agent.

When the specific ion is excessively contained, the excess specific ion can be removed by adsorption with an adsorbent (e.g., silica) or washing with water, and the content of the specific ion can be adjusted to be within the above range.

### <Other Component>

The present surface treating agent may contain components other than the fluorine-containing ether compound and the specific ion (hereinafter also referred to as “other components”).

Specific examples of other components include at least one component of a fluorine-containing compound other than the fluorine-containing ether compound described above and the following impurities, and a liquid medium.

Examples of other fluorine-containing compounds include a fluorine-containing compound formed as a by-product in the process for producing the fluorine-containing ether compound (hereinafter also referred to as “by-product fluorine-containing compound”) and a known fluorine-containing compound used for the same purpose as the fluorine-containing ether compound.

The other fluorine-containing compound is preferably a compound which is less likely to deteriorate the characteristics of the fluorine-containing ether compound.

The content of the other fluorine-containing compound is preferably less than 70% by mass, more preferably less than 50% by mass, even more preferably less than 20% by mass, particularly preferably less than 10% by mass, and most preferably less than 5% by mass with respect to the total mass of the surface treating agent, from the viewpoint of fully exhibiting the characteristics of the fluorine-containing ether compound.

The by-product fluorine-containing compound includes an unreacted fluorine-containing compound in the synthesis of the fluorine-containing ether compound. When the present composition contains a by-product fluorine-containing compound, a purification step of removing the by-product fluorine-containing compound or reducing the amount of the by-product fluorine-containing compound can be simplified.

Examples of the known fluorine-containing compounds include those described in the following literatures:
perfluoropolyether-modified aminosilanes described in Japanese Unexamined Patent Application Publication No. H11-029585;
silicon-containing organic fluorine-containing polymers described in Japanese Patent No. 2874715;
organic silicon compounds described in Japanese Unexamined Patent Application Publication No. 2000-144097;
perfluoropolyether-modified aminosilanes described in Japanese Unexamined Patent Application Publication No. 2000-327772;
fluorinated siloxanes described in Japanese Translation of PCT International Application Publication No. 2002-506887;
organic silicon compounds described in Japanese Translation of PCT International Application Publication No. 2008-534696;
fluorinated modified hydrogen-containing polymers described in Japanese Patent No. 4138936;
compounds described in US Patent Publication No. 2010/0129672, International Patent Publication No. WO 2014/126064, and Japanese Unexamined Patent Application Publication No. 2014-070163;
organosilicon compounds described in International Patent Publication No. WO 2011/060047 and International Patent Publication No. WO 2011/059430;
fluorine-containing organosilane compounds described in International Patent Publication No. WO 2012/064649;
fluorooxyalkylene group-containing polymers described in Japanese Unexamined Patent Application Publication No. 2012-72272;
fluorine-containing ether compounds described in International Patent Publication No. WO 2013/042732, International Patent Publication No. WO 2013/121984, International Patent Publication No. WO 2013/121985, International Patent Publication No. WO 2013/121986, International Patent Publication No. WO 2014/163004, Japanese Unexamined Patent Application Publication No. 2014-080473, International Patent Publication No. WO 2015/087902, International Patent Publication No. WO 2017/038830, International Patent Publication No. WO 2017/038832, and International Patent Publication No. WO 2017/187775;
perfluoro (poly) ether-containing silane compounds described in Japanese Unexamined Patent Application Publication No. 2014-218639, International Patent Publication No. WO 2017/022437, International Patent Publication No. WO 2018/079743, and International Patent Publication No. WO 2018/143433;
fluoropolyether group-containing polymer-modified silanes described in Japanese Unexamined Patent Application Publication No. 2015-199906, Japanese Unexamined Patent Application Publication No. 2016-204656, Japanese Unexamined Patent Application Publication No. 2016-210854, and Japanese Unexamined Patent Application Publication No. 2016-222859; and
   fluorine-containing ether compounds described in International Patent Publication No. WO 2018/216630, International Patent Publication No. WO 2019/039226, International Patent Publication No. WO 2019/039341, International Patent Publication No. WO 2019/039186, International Patent Publication No. WO 2019/044479, Japanese Unexamined Patent Application Publication No. 2019-44158, and International Patent Publication No. WO 2019/163282.

In addition, examples of commercially available products of the fluorine-containing compound include KY-100 series (KY-178, KY-185, KY-195, etc.) manufactured by Shin-Etsu Chemical Co., Ltd.; SURECO AF series such as SURECO (registered trademark)2101S manufactured by AGC Inc.; and OPTOOL (registered trademark) DSX, OPTOOL (registered trademark) AES, OPTOOL (registered trademark) UF503, and OPTOOL (registered trademark) UD509 manufactured by Daikin Industries, Ltd.

When the present surface treating agent contains another fluorine-containing compound, the content of the other fluorine-containing compound is preferably 60% by mass or less, more preferably 30% by mass, and more preferably 10% by mass or less with respect to the total content of the fluorine-containing ether compound and the other fluorine-containing compound in the present surface treating agent.

The total content of the fluorine-containing ether compound and other fluorine-containing compounds in the present surface treating agent is preferably 0.01% by mass or more, and more preferably 0.03% by mass or more.

If the content of the fluorine-containing ether compound and other fluorine-containing compounds is within the above ranges, the surface layer is excellent in water/oil repellency, friction durability, fingerprint stain removability, lubricity, and appearance.

When the present surface treating agent contains a liquid medium, this surface treating agent can be used as a coating liquid. The coating liquid may be a liquid, may be a solution, or may be a dispersion.

The liquid medium is preferably an organic solvent. The organic solvent may be a fluorine-based organic solvent and non-fluorine-based organic solvent, or may contain both solvents.

Examples of the fluorine-based organic solvent include fluorinated alkanes, fluorinated aromatic compounds, fluoroalkyl ethers, fluorinated alkylamines, and fluoroalcohols.

The fluorinated alkane is preferably a compound having 4 to 8 carbon atoms. Examples of the commercially available product include C₆F₁₃H (ASAHIKLIN (registered trademark) AC-2000 manufactured by AGC Inc.), C₆F₁₃C₂H₅ (ASAHIKLIN (registered trademark) AC-6000 manufactured by AGC Inc.), and C₂F₅CHFCHFCF₃ (Vertrel (registered trademark) XF manufactured by the Chemours Company).

Specific examples of the fluorinated aromatic compound include hexafluorobenzene, trifluoromethylbenzene, perfluorotoluene, and bis(trifluoromethyl)benzene.

The fluoroalkyl ether is preferably a compound having 4 to 12 carbon atoms. Examples of the commercially available product include CF₃CH₂OCF₂CF₂H (ASAHIKLIN (registered trademark) AE-3000 manufactured by AGC Inc.), C₄F₉OCH₃ (Novec (registered trademark) 7100 manufactured by 3M), C₄F₉OC₂H₅ (Novec (registered trademark) 7200 manufactured by 3M), and C₂F₅CF(OCH₃)C₃F₇ (Novec (registered trademark) 7300 manufactured by 3M).

Specific examples of the fluorinated alkylamine include perfluorotripropylamine and perfluorotributylamine.

Specific examples of the fluoroalcohol include 2,2,3,3-tetrafluoropropanol, 2,2,2-trifluoroethanol, and hexafluoroisopropanol.

The non-fluorine-based organic solvent is preferably a compound consisting only of a hydrogen atom and a carbon atom and a compound consisting only of a hydrogen atom, a carbon atom, and an oxygen atom, and examples thereof include a hydrocarbon-based organic solvent, an alcohol-based organic solvent, a ketone-based organic solvent, an ether-based organic solvent, and an ester-based organic solvent.

When the present surface treating agent contains a liquid medium, the present surface treating agent preferably contains 60 to 99.999% by mass, preferably 85 to 99.99% by mass, and even more preferably 90 to 99.9% by mass of the liquid medium.

The present surface treating agent may further contain known additives such as an acid catalyst and a basic catalyst that promote hydrolysis and condensation reaction of a hydrolyzable silyl group.

The content of the additives is preferably 10% by mass or less, and more preferably 1% by mass or less with respect to the total mass of the present surface treating agent.

### [Article]

The article of the present invention (hereinafter also referred to as “the present article”) preferably has a substrate, a surface layer arranged on the substrate, and an underlying layer between the substrate and the surface layer.

The surface layer is a layer formed of the surface treating agent described above and contains a condensate of the fluorine-containing ether compound.

The material and shape of the substrate may be appropriately selected according to the application of the present article and the like. Examples of the material of the substrate include glass, resin, sapphire, metal, ceramic, stone, and composite materials thereof. The glass may be chemically strengthened. In particular, examples of the substrate required to have water/oil repellency include a substrate for a touch panel, a substrate for a display, and a substrate constituting a housing of electronic equipment. The substrate for a touch panel and the substrate for a display have translucency. The expression “having translucency” means that the normal incidence type visible light transmittance according to JIS R3106:1998 (ISO 9050:1990) is 25% or more. The material of the substrate for a touch panel is preferably glass or a transparent resin.

The substrate may be obtained by subjecting the surface on which the underlying layer is provided to a surface treatment such as a corona discharge treatment, a plasma treatment, or a plasma graft polymerization treatment. The surface-treated surface has further excellent adhesiveness between the substrate and the underlying layer, and as a result, the friction durability of the surface layer is further improved. The surface treatment is preferably a corona discharge treatment or a plasma treatment from the viewpoint of further excellent friction durability of the surface layer.

The underlying layer is preferably a layer containing an oxide containing silicon (preferably silicon oxide), and may further contain other elements. When the underlying layer contains silicon oxide, the reactive silyl group of the fluorine-containing ether compound is dehydrated and condensed to form a Si—O—Si bond between the underlying layers, and the surface layer having excellent friction durability is formed.

The content of silicon oxide in the underlying layer is preferably 65% by mass or more, and is more preferably 80% by mass or more, even more preferably 85% by mass or more, and particularly preferably 90% by mass or more. When the content of silicon oxide is equal to or more than the lower limit value, a Si—O—Si bond is sufficiently formed in the underlying layer, and the mechanical characteristics of the underlying layer are sufficiently secured. The content of silicon oxide is the remainder obtained by subtracting the sum of the total contents of other elements (in the case of oxides, the amount in terms of oxides) from the mass of the underlying layer.

From the viewpoint of durability of the surface layer, the oxide in the underlying layer preferably further contains one or more elements selected from an alkali metal element, an alkaline earth metal element, a platinum group element, boron, aluminum, phosphorus, titanium, zirconium, iron, nickel, chromium, molybdenum, and tungsten. By containing these elements, the bond between the underlying layer and the fluorine-containing ether compound is strengthened, and the friction durability is thus improved.

The thickness of the underlying layer is preferably 1 to 200 nm, and more preferably 2 to 20 nm. When the thickness of the underlying layer is equal to or more than the lower limit value, the effect of improving the adhesiveness by the underlying layer tends to be sufficiently obtained. When the thickness of the underlying layer is equal to or less than the upper limit value, the underlying layer itself has enhanced friction durability. Examples of a method of measuring the thickness of the underlying layer include a method by observing a cross-section of the underlying layer with an electron microscope (SEM, TEM, etc.), and a method using, for example, an optical interference film thickness meter, a spectroscopic ellipsometer, or a step profiler.

Examples of the method of forming the underlying layer include a method of depositing a vapor deposition material having a desired composition of the underlying layer on the surface of the substrate.

An example of the vapor deposition method is a vacuum deposition method. The vacuum deposition method is a method of evaporating a vapor deposition material in a vacuum tank to attach it to the surface of the substrate.

The temperature during vapor deposition (for example, temperature of the boat on which the vapor deposition material is installed when a vacuum deposition apparatus is used) is preferably 100 to 3,000° C., and more preferably 500 to 3,000° C.

The pressure during vapor deposition (for example, absolute pressure in the tank in which the vapor deposition material is installed when a vacuum deposition apparatus is used) is preferably 1 Pa or less, and more preferably 0.1 Pa or less.

When the underlying layer is formed using a vapor deposition material, one vapor deposition material may be used, or two or more vapor deposition materials containing different elements may be used.

Examples of the method of evaporating the vapor deposition material include a resistance heating method of melting and evaporating the vapor deposition material on a resistance heating boat made of a high melting point metal; and an electron gun method of irradiating the vapor deposition material with an electron beam and directly heating the vapor deposition material to melt the surface and evaporate the vapor deposition material. The method of evaporating the vapor deposition material is preferably the electron gun method because a high melting point substance can also be evaporated since the vapor deposition material can be locally heated, and there is no concern about reaction with a container or mixing of impurities since a part not hit by an electron beam is at a low temperature. The vapor deposition material used in the electron gun method is preferably a molten granular material or a sintered body from the viewpoint of being less likely to scatter even when an air flow is generated.

The surface layer contains a condensate of the fluorine-containing ether compound. The condensate of the present fluorine-containing ether compound includes a structure in which a Si—O—Si bond is formed by an intermolecular condensation reaction of a silanol group (Si—OH) which is formed by a hydrolysis reaction of the hydrolyzable silyl group in the present fluorine-containing ether compound; and a structure in which a Si—O—Si bond is formed by a condensation reaction of the silanol group in the fluorine-containing ether compound with a silanol group or a Si-OM group (where M is an alkali metal element) on the surface of the substrate or the underlying layer. In addition, the surface layer may contain a condensate of a fluorine-containing compound other than the fluorine-containing ether compound. In other words, the surface layer contains the fluorine-containing compound having a reactive silyl group in a state where a part or all of the reactive silyl group of the fluorine-containing compound undergoes a condensation reaction.

The thickness of the surface layer is preferably 1 to 100 nm, and more preferably 1 to 50 nm. When the thickness of the surface layer is equal to or more than the lower limit value, the effect of the surface layer can be sufficiently obtained. When the thickness of the surface layer is equal to or less than the upper limit value, the utilization efficiency is high.

The thickness of the surface layer is a thickness obtained by an X-ray diffractometer for thin film analysis. The thickness of the surface layer can be calculated from the vibration period of the interference pattern by obtaining the interference pattern of the reflected X-ray by the X-ray reflectance method using the X-ray diffractometer for thin film analysis.

The present article is preferably a touch panel. In this case, the surface layer is preferably formed on the surface of a member constituting a plane of a touch panel to be touched with fingers.

### [Method for Producing Article]

The method for producing the present article is a method of forming a surface layer on a substrate by a dry coating method or a wet coating method using the present surface treating agent.

When the present surface treating agent contains no liquid medium, this surface treating agent can be used as it is in a dry coating method. Examples of the dry coating method include techniques such as vacuum deposition, CVD, and sputtering. The vacuum deposition method can be suitably used from the viewpoint of suppressing decomposition of the fluorine-containing ether compound and convenience of the apparatus.

For vacuum deposition, a pellet-like substance that supports the fluorine-containing ether compound and a metal compound on a metal porous body made of a metal material such as iron or steel may be used. The pellet-like substance that supports the fluorine-containing ether compound and the metal compound can be produced by impregnating the metal porous body with the present surface treating agent containing a liquid medium and drying it to remove the liquid medium.

When the present surface treating agent contains a liquid medium, this surface treating agent can be suitably used in a wet coating method. Examples of the wet coating method include a spin coating method, a wipe coating method, a spray coating method, a squeegee coating method, a dip coating method, a die coating method, an inkjet method, a flow coating method, a roll coating method, a casting method, a Langmuir-Blodgett method, and a gravure coating method.

In order to improve friction durability of the surface layer, an operation for promoting the reaction between the fluorine-containing ether compound and the substrate (or the underlying layer) may be performed, if necessary. Examples of the operation include heating, humidification, and light irradiation. For example, a substrate on which the surface layer is formed can be heated in the atmosphere having moisture to promote reactions such as a hydrolysis reaction of a hydrolyzable group, a reaction of a hydroxyl group or the like on the surface of the substrate with a silanol group, and generation of a siloxane bond by a condensation reaction of a silanol group.

After the surface treatment, the compound in the surface layer, which is a compound that is not chemically bonded to another compound or the substrate, may be removed, if necessary. Specific examples include a method of pouring a solvent on the surface layer and a method of wiping the surface layer with a cloth soaked with the solvent.

### EXAMPLES

The present invention is described in detail below with reference to examples. Examples 2 to 7, 9 to 11, 13 to 15, 18 to 20, 23 to 25, and 28 to 30 are Examples, and Examples 1, 8, 12, 16, 17, 21, 22, 26, 27 and 31 are Comparative Examples. However, the present invention is not limited to these Examples. The amount of each component in the table to be described later indicates the mass standard.

### [Measurement of Specific Ion Content]

The content of iodide ion in an iodide ion-containing solution, the content of bromide ion in a bromide ion-containing solution, and the contents of iodide ion and bromide ion in the surface treating agent were determined by an external standard method by measuring iodide ions and bromide ions using an ion chromatograph apparatus below.

A sample for measuring the contents of the iodide ion and the bromide ion was prepared by adding ultrapure water to the iodide ion-containing solution, the bromide ion-containing solution, or the surface treating agent to extract iodide ions and bromide ions into the aqueous phase.
Instrument name: Dionex ICS-5000 (Thermo Scientific)
Column: Dionex Ionpac AS19
Temperature: 30° C.
Flow rate: 1.0 mL/min
Detector: Electric conductivity

### [Production of Fluorine-Containing Ether Compound A1-1]

Compound A1-1 was obtained in the same manner as in the method described in Example 11 of International Patent Publication No. WO 2017/038830.

CF₃—(OCF₂CF₂OCF₂CF₂CF₂CF₂)₁₃(OCF₂CF₂)—OCF₂CF₂CF₂—C(O)NH—CH₂—C[CH₂CH₂CH₂—Si(OCH₃)₃]₃ (A1-1)

### [Production of Fluorine-Containing Ether Compound A1-2]

Compound A1-2 was obtained in the same manner as in the method described in Synthesis Example 8 of International Patent Publication No. WO 2018/079743.

CF₃—(OCF₂CF₂)₂O(OCF₂)₁₆—OCF₂CH₂CH₂CH₂—Si[CH₂CH₂CH₂Si(OCH₃)₃]₃ (A1-2)

### [Production of Fluorine-Containing Ether Compound A1-3]

Compound A1-3 was obtained according to the method described in Synthesis Example 8 of International Patent Publication No. WO 2018/079743.

CF₃O(CF₂CF₂O)₂O(CF₂O)₁₆CF₂CH₂CH₂CH₂Si[CH₂CH₂CH₂Si(OCH₃)₃]₃ (A1-3)

### [Production of Fluorine-Containing Ether Compound A1-4]

Compound A1-4 was obtained according to the method described in Example 1 of Japanese Unexamined Patent Application Publication No. 2016-204656.

CF₃O(CF₂CF₂O)₂₃(CF₂O)₂₀C[CH₂CH₂CH₂Si(OCH₃)₃]₂[OCH₂CH₂CH₂Si(OCH₃)₃] (A1-4)

### [Preparation of Surface Treating Agent 1]

First, 1 g of fluorine-containing ether compound A1-1 was mixed with 9 g of C₄F₉OC₂H₅(manufactured by 3M, Novec (registered trademark) 7200), which is a fluorine-based organic solvent, to give a surface treating agent 1 in which the content of the fluorine-containing ether compound A1-1 was 10% by mass.

Note that the contents of the iodide ion and the bromide ion in the surface treating agent 1 were each 0 ppm by mass upon measurement.

### [Preparation of Surface Treating Agent 2]

First, 100 g of Novec 7200, which is a fluorine-based organic solvent was mixed with 3 g of an aqueous hydroiodic acid solution and stirred vigorously, followed by liquid separation, to give a fluorine-based organic solvent phase.

To 90 g of the resulting fluorine-based organic solvent phase, 50 g of molecular sieves was charged. The sieves were allowed to stand for one week and filtered to give an iodide ion-containing solution 1 containing iodide ions and Novec 7200.

Using the resulting iodide ion-containing solution 1, the content of iodide ions in the iodide ion-containing solution 1 was measured by the ion chromatography method described above.

Next, 1 g of fluorine-containing ether compound A1-1 was mixed with 4 g of Novec 7200 to give a polymer solution 1 in which the content of the fluorine-containing ether compound A1-1 was 20% by mass.

The polymer solution 1 was mixed with the iodide ion-containing solution 1 and Novec 7200 so that the content of fluorine-containing ether compound A1-1 in the surface treating agent was 10% by mass and the content of iodide ion in the surface treating agent was the value listed in Table 1 to give a surface treating agent 2.

### [Preparation of Surface Treating Agents 3 to 8]

Surface treating agents 3 to 8 were obtained in the same manner as the preparation of the surface treating agent 2 except that the mixing ratio of the polymer solution 1, the iodide ion-containing solution 1, and Novec 7200 was appropriately adjusted so that the content of fluorine-containing ether compound A1-1 in the surface treating agent was 10% by mass and the content of iodide ion in the surface treating agent was the value listed in Table 1.

### [Preparation of Surface Treating Agent 9]

First, 100 g of Novec 7200, which is a fluorine-based organic solvent, was mixed with 3 g of an aqueous hydrobromic acid solution and stirred vigorously, followed by liquid separation, to give a fluorine-based organic solvent phase.

To 90 g of the resulting fluorine-based organic solvent phase, 50 g of molecular sieves was charged. The sieves were allowed to stand for one week and filtered to give a bromide ion-containing solution 1 containing bromide ions and Novec 7200.

Using the resulting bromide ion-containing solution 1, the content of bromide ions in the bromide ion-containing solution 1 was measured by the ion chromatography described above.

The polymer solution 1 was mixed with the bromide ion-containing solution 1 and Novec 7200 so that the content of fluorine-containing ether compound A1-1 in the surface treating agent was 10% by mass; and the content of bromide ions in the surface treating agent was the value listed in Table 1 to give a surface treating agent 9.

### [Preparation of Surface Treating Agents 10 to 12]

Surface treating agents 10 to 12 were obtained in the same manner as in the preparation of the surface treating agent 9, except that the mixing ratio of the polymer solution 1, the bromide ion-containing solution 1, and Novec 7200 was appropriately adjusted so that the content of fluorine-containing ether compound A1-1 in the surface treating agent was 10% by mass; and the content of bromide ions in the surface treating agent was the value listed in Table 1.

### [Preparation of Surface Treating Agents 13 to 16]

The polymer solution 1 was mixed with the iodide ion-containing solution 1, the bromide ion-containing solution 1, and Novec 7200 so that the content of fluorine-containing ether compound A1-1 in the surface treating agent was 10% by mass; and the contents of iodide ions and bromide ions in the surface treating agent were the values listed in Table 1 to give surface treating agents 13 to 16.

### [Preparation of Surface Treating Agent 17]

A surface treating agent 17 was obtained in the same manner as in the preparation of the surface treating agent 1 except that fluorine-containing ether compound A1-2 was used instead of fluorine-containing ether compound A1-1.

Note that the contents of the iodide ion and the bromide ion in the surface treating agent 17 were each 0 ppm by mass upon measurement.

### [Preparation of Surface Treating Agent 18]

First, 1 g of fluorine-containing ether compound A1-2 was mixed with 4 g of Novec 7200 to give a polymer solution 2 in which the content of the fluorine-containing ether compound A1-2 was 20% by mass.

A surface treating agent 18 was obtained in the same manner as the preparation of the surface treating agent 2 except that the polymer solution 2 was used instead of the polymer solution 1.

### [Preparation of Surface Treating Agents 19 to 21]

Surface treating agents 19 to 21 were obtained in the same manner as in the preparation of the surface treating agents 4, 7, and 8 except that the polymer solution 2 was used instead of the polymer solution 1.

### [Preparation of Surface Treating Agent 22]

First, 1 g of fluorine-containing ether compound A1-3 was mixed with 4 g of Novec 7200 to give a polymer solution 3 in which the content of fluorine-containing ether compound A1-3 was 20% by mass.

A surface treating agent 22 was obtained in the same manner as in the preparation of the surface treating agent 1 except that the polymer solution 3 was used instead of the polymer solution 1.

### [Preparation of Surface Treating Agents 23 to 26]

Surface treating agents 23 to 26 were obtained in the same manner as in the preparation of the surface treating agent 22, except that the mixing ratio of the polymer solution 1, the iodide ion-containing solution 1, and Novec 7200 was appropriately adjusted so that the content of fluorine-containing ether compound A1-3 in the surface treating agent was 10% by mass; and the content of the iodide ions in the surface treating agent was the value listed in Table 1.

### [Preparation of Surface Treating Agent 27]

First, 1 g of fluorine-containing ether compound A1-4 was mixed with 4 g of Novec 7200 to give a polymer solution 4 in which the content of the fluorine-containing ether compound A1-4 was 20% by mass.

A surface treating agent 27 was obtained in the same manner as in the preparation of the surface treating agent 1 except that the polymer solution 4 was used instead of the polymer solution 1.

### [Preparation of Surface Treating Agents 28 to 31]

Surface treating agents 28 to 31 were obtained in the same manner as in the preparation of the surface treating agent 27, except that the mixing ratio of the polymer solution 1, the bromide ion-containing solution 1, and Novec 7200 was appropriately adjusted so that the content of fluorine-containing ether compound A1-4 in the surface treating agent was 10% by mass; and the content of the bromide ions in the surface treating agent was the value listed in Table 1.

### Examples 1 to 31

0.5 g of each surface treating agent obtained as described above was filled in a boat made of molybdenum in the vacuum deposition apparatus (manufactured by ULVAC Co., VTR-350M), and inside of the vacuum deposition apparatus was evacuated of air to a level of 1×10⁻³ Pa or less. The boat on which the surface treating agent was placed was heated at a temperature raising rate of 10° C./min or less, and at the time when the vapor deposition rate by a quartz oscillator film thickness meter exceeded 1 nm/see, the shutter was opened to initiate film deposition on the surface of a substrate (chemically tempered glass). When the film thickness became about 50 nm, the shutter was closed to terminate film deposition on the surface of the substrate. The substrate, on which the surface treating agent was deposited, was subjected to heat treatment at 200° C. for 30 minutes, followed by washing with dichloropentafluoropropane (manufactured by AGC Inc., AK-225) to obtain each article of Examples 1 to 31 having a surface layer on the surface of the substrate.

### [Long-Term Storage Stability Test]

A friction test was conducted on the surface layer of each article of Examples 1 to 31 by using a reciprocating traverse testing machine (manufactured by KNT Co.) in accordance with JIS L0849:2013 (ISO 105-X12:2001) by reciprocating steel wool Bon Star (#0000) at a pressure of 98.07 kPa at a speed of 320 cm/min. The number of reciprocations A was recorded when the water contact angle of the surface layer decreased by 8° after friction.

The respective articles corresponding to Examples 1 to 31 were obtained in the same manner as the production method of the respective articles in Examples 1 to 31 described above, except that the surface treating agents 1 to 31 which had been stored for 2 years under the conditions of humidity of 40% RH and 25° C. was used. The friction test was conducted on the surface layer of each obtained article, and the number of reciprocations B when the water contact angle of the surface layer after friction decreased by 8° was recorded.

Based on the number of reciprocations A and B obtained, the ratio of the reciprocation B to the reciprocation A (the number of reciprocations B/the number of reciprocations A) was determined to evaluate the long-term storage stability according to the following criteria. The closer the above ratio was to 1.00, the better the long-term storage stability of the surface treating agent was. The evaluation results are shown in Table 1.

Note that the water contact angle was measured by using a contact angle measuring apparatus (manufactured by Kyowa Interface Science Co., Ltd., DM-500) by depositing 2 μL of distilled water on the surface of the surface layer, which was the arithmetic mean value at five different locations of the surface layer. For the calculation of the water contact angle, a 2θ method was employed.

A (good): The ratio (number of reciprocations B/number of reciprocations A) was 0.96 or more and 1.00 or less.

B (acceptable): The ratio (number of reciprocations B/number of reciprocations A) was 0.90 or more and less than 0.96.

C (poor): The ratio (number of reciprocations B/number of reciprocations A) was less than 0.90.

### [Acid Resistance Test]

For the surface layer of each article of Examples 1 to 31, the water contact angle of the surface layer was measured by the method described above.

Next, each article of Examples 1 to 31 was immersed in 5 N hydrochloric acid at 60° C., then washed with water and air-dried. Thereafter, the friction test described above was carried out on the surface layer of the article under the condition that the number of reciprocations was 15,000, and the water contact angle of the surface layer was measured by the method described above.

Based on the water contact angle before and after immersion in hydrochloric acid, the acid resistance was evaluated according to the following evaluation criteria. The smaller the decrease in the water contact angle after immersion in hydrochloric acid, the smaller the deterioration in the durability of the surface layer due to acid, and the better the acid resistance.

A (good): The change in water contact angle before and after immersion in hydrochloric acid is 2 degrees or less.

B (acceptable): The change in water contact angle before and after immersion in hydrochloric acid is more than 2 degrees and 5 degrees or less.

C (poor): The change in water contact angle before and after immersion in hydrochloric acid is more than 5 degrees.

TABLE 1

| | Exam- | Exam- | Exam- | Exam- | Exam- | Exam- | Exam- | Exam- | Exam- | Exam- |
|---|---|---|---|---|---|---|---|---|---|---|
| | ple 1 | ple 2 | ple 3 | ple 4 | ple 5 | ple 6 | ple 7 | ple 8 | ple 9 | ple 10 |
| Type of surface treating agent | 1 | 2 | 3 | 4 | 5 | 6 | 7 | 8 | 9 | 10 |
| Type of fluorine-containing polymer | A1-1 | A1-1 | A1-1 | A1-1 | A1-1 | A1-1 | A1-1 | A1-1 | A1-1 | A1-1 |
| Content of iodide ion in surface | 0.00 | 0.10 | 0.20 | 0.50 | 1.20 | 1.50 | 1.90 | 2.20 | 0.00 | 0.00 |
| treating agent (ppm by mass) | | | | | | | | | | |
| Content of bromide ion in surface | 0.00 | 0.00 | 0.00 | 0.00 | 0.00 | 0.00 | 0.00 | 0.00 | 0.10 | 0.50 |
| treating agent (ppm by mass) | | | | | | | | | | |
| Acid resistance | C | B | A | A | A | A | A | A | B | A |
| Long-term storage stability | A | A | A | A | A | A | B | C | A | A |

| | Exam- | Exam- | Exam- | Exam- | Exam- | Exam- | Exam- | Exam- | Exam- | Exam- | Exam- |
|---|---|---|---|---|---|---|---|---|---|---|---|
| | ple 11 | ple 12 | ple 13 | ple 14 | ple 15 | ple 16 | ple 17 | ple 18 | ple 19 | ple 20 | ple 21 |
| Type of surface treating agent | 11 | 12 | 13 | 14 | 15 | 16 | 17 | 18 | 19 | 20 | 21 |
| Type of fluorine-containing polymer | A1-1 | A1-1 | A1-1 | A1-1 | A1-1 | A1-1 | A1-2 | A1-2 | A1-2 | A1-2 | A1-2 |
| Content of iodide ion in surface | 0.00 | 0.00 | 0.05 | 0.50 | 0.90 | 1.20 | 0.00 | 0.10 | 0.50 | 1.90 | 2.20 |
| treating agent (ppm by mass) | | | | | | | | | | | |
| Content of bromide ion in surface | 1.90 | 2.20 | 0.05 | 0.50 | 0.90 | 1.20 | 0.00 | 0.00 | 0.00 | 0.00 | 0.00 |
| treating agent (ppm by mass) | | | | | | | | | | | |
| Acid resistance | A | A | B | A | A | A | C | B | A | A | A |
| Long-term storage stability | B | C | A | A | B | C | A | A | A | B | C |

| | Exam- | Exam- | Exam- | Exam- | Exam- | Exam- | Exam- | Exam- | Exam- | Exam- |
|---|---|---|---|---|---|---|---|---|---|---|
| | ple 22 | ple 23 | ple 24 | ple 25 | ple 26 | ple 27 | ple 28 | ple 29 | ple 30 | ple 31 |
| Type of surface treating agent | 22 | 23 | 24 | 25 | 26 | 27 | 28 | 29 | 30 | 31 |
| Type of fluorine-containing polymer | A1-3 | A1-3 | A1-3 | A1-3 | A1-3 | A1-4 | A1-4 | A1-4 | A1-4 | A1-4 |
| Content of iodide ion in surface | 0.00 | 0.10 | 0.50 | 1.90 | 2.20 | 0.00 | 0.00 | 0.00 | 0.00 | 0.00 |
| treating agent (ppm by mass) | | | | | | | | | | |
| Content of bromide ion in surface | 0.00 | 0.00 | 0.00 | 0.00 | 0.00 | 0.00 | 0.10 | 0.50 | 1.90 | 2.20 |
| treating agent (ppm by mass) | | | | | | | | | | |
| Acid resistance | C | B | A | A | A | C | B | A | A | A |
| Long-term storage stability | A | A | A | B | C | A | A | A | B | C |

As shown in Table 1, it was confirmed that the surface treating agent containing a fluorine-containing ether compound and a predetermined amount of the specific ion was capable of forming a surface layer excellent in long-term storage stability and acid resistance (Examples 2 to 7, Examples 9 to 11, Examples 13 to 15, Examples 18 to 20, Examples 23 to 25, and Examples 28 to 30).

What is claimed is:

1. A surface treating agent comprising:
a fluorine-containing ether compound having a fluoropolyether chain and a reactive silyl group; and
one or more ions selected from the group consisting of an iodide ion and a bromide ion,
wherein a content of the ions is 0.05 to 2.00 ppm by mass with respect to a total mass of the surface treating agent.

2. The surface treating agent according to claim 1, wherein the content of the ion is 0.20 to 1.50 ppm by mass with respect to the total mass of the surface treating agent.

3. The surface treating agent according to claim 1, wherein a content of the one or more ions selected from the group consisting of an iodide ion and a bromide ion is 0.5 to 20 ppm by mass with respect to a total mass of the fluorine-containing ether compound in the surface treating agent.

4. The surface treating agent according to claim 2, wherein a content of the one or more ions selected from the group consisting of an iodide ion and a bromide ion is 0.5 to 20 ppm by mass with respect to a total mass of the fluorine-containing ether compound in the surface treating agent.

5. The surface treating agent according to claim 1, wherein a molecular weight per fluoropolyether chain is 2,000 to 20,000.

6. The surface treating agent according to claim 2, wherein a molecular weight per fluoropolyether chain is 2,000 to 20,000.

7. The surface treating agent according to claim 1, wherein the fluorine-containing ether compound is a compound represented by formula (A1), (A2), or (A3):
[R^{f1}—(OR^{f11})_{y1}—O—R¹]ⱼ-L¹-(R¹¹-T¹¹)ₓ₁ (A1)
(T³¹-R³¹)ₓ₃-L³-R³—(OR^{f12})_{y2}—O—R²-L²-(R²¹-T²¹)ₓ₂ (A2)
Q¹[-(OR^{f13})_{y3}—O—R⁴-L⁴-(R⁴¹-T⁴¹)ₓ₄]ᵣ₁ (A3)
wherein
R^{f1} is a fluoroalkyl group having 1 to 20 carbon atoms, and when there is a plurality of R^{f1}, the plurality of R^{f1} is the same as or different from each other;
R^{f11} is a fluoroalkylene group having 1 to 6 carbon atoms, and when there is a plurality of R^{f11}, the plurality of R^{f11} is the same as or different from each other;
R¹ is an alkylene group or a fluoroalkylene group, and when there is a plurality of R¹, the plurality of R¹ is the same as or different from each other;
L¹ is a single bond or a j+x1 valent organic group optionally having N, O, S, or Si and a branch point, wherein atoms bonded to R¹ and R¹¹ are each independently N, O, S, or Si, a carbon atom constituting the branch point, or a carbon atom having an oxo group (═O);
R¹¹ is an alkylene group in which an atom bonded to L¹ is optionally an etheric oxygen atom and which optionally has an etheric oxygen atom between carbon-carbon atoms;
T¹¹ is —SiR^{a11}_{z11}R^{a12}_{3-z11};
R^{a11} is a hydroxy group or a hydrolyzable group, and when there is a plurality of R^{a11}, the plurality of R^{a11} is the same as or different from each other;
R^{a12} is a non-hydrolyzable group, and when there is a plurality of R^{a12}, the plurality of R^{a12} is the same as or different from each other;
j is an integer of 1 or more;
z11 is an integer of 1 to 3;
x1 is an integer of 1 or more;
y1 is an integer of 1 or more, and when there is a plurality of
y1, the plurality of y1 is the same as or different from each other;
R^{f12} is a fluoroalkylene group having 1 to 6 carbon atoms, and when there is a plurality of R^{f12}, the plurality of R^{f12} is the same as or different from each other;
R² and R³ are each independently an alkylene group or a fluoroalkylene group;
L² is a single bond or a 1+x2 valent organic group optionally having N, O, S, or Si and a branch point, wherein atoms bonded to R² and R²¹ are each independently N, O, S, or Si, a carbon atom constituting the branch point, or a carbon atom having an oxo group (═O);
R²¹ is an alkylene group in which an atom adjacent to L² is optionally an etheric oxygen atom and which optionally has an etheric oxygen atom between carbon-carbon atoms;
L³ is a single bond or a 1+x3 valent organic group optionally having N, O, S, or Si and a branch point, wherein atoms bonded to R³ and R³¹ are each independently N, O, S, or Si, a carbon atom constituting the branch point, or a carbon atom having an oxo group (═O);
R³¹ is an alkylene group in which an atom adjacent to L³ is optionally an etheric oxygen atom and which optionally has an etheric oxygen atom between carbon-carbon atoms;
T²¹ and T³¹ are each independently —SiR^{a21}_{z21}R^{a22}_{3-z21};
R^{a21} is a hydroxy group or a hydrolyzable group, and when there is a plurality of R^{a21}, the plurality of R^{a21} is the same as or different from each other;
R^{a22} is a non-hydrolyzable group, and when there is a plurality of R^{a22}, the plurality of R^{a22} is the same as or different from each other;
z21 is an integer of 1 to 3;
x2 and ×3 are each independently an integer of 1 or more;
y2 is an integer of 1 or more;
Q¹ is an r1 valent group having a branch point;
R^{f13} is a fluoroalkylene group having 1 to 6 carbon atoms, and when there is a plurality of R^{f13}, the plurality of R^{f13} is the same as or different from each other;
each R⁴ is independently an alkylene group or a fluoroalkylene group;
L⁴ is a single bond or a 1+x4 valent organic group optionally having N, O, S, or Si and a branch point, wherein atoms bonded to R⁴ and R⁴¹ are each independently N, O, S, or Si, a carbon atom constituting the branch point, or a carbon atom having an oxo group (═O);
R⁴¹ is an alkylene group in which an atom adjacent to L⁴ is optionally an etheric oxygen atom and which optionally has an etheric oxygen atom between carbon-carbon atoms;
T⁴¹ is —SiR^{a41}_{z41}R^{a42}_{3-z41};
R^{a41} is a hydroxy group or a hydrolyzable group, and when there is a plurality of R^{a41}, the plurality of Rₐ₄₁ is the same as or different from each other;
R^{a42} is a non-hydrolyzable group, and when there is a plurality of R^{a42}, the plurality of R^{a42} is the same as or different from each other;
z41 is an integer of 1 to 3;
x4 is an integer of 1 or more;
y3 is an integer of 1 or more; and
r1 is 3 or 4.

8. The surface treating agent according to claim 2, wherein the fluorine-containing ether compound is a compound represented by formula (A1), (A2), or (A3):
[R^{f1}—(OR^{f11})_{y1}—O—R¹]ⱼ-L¹-(R¹¹-T¹¹)ₓ₁ (A1)
(T³¹-R³¹)ₓ₃-L³-R³—(OR^{f12})_{y2}—O—R²-L²-(R²¹-T²¹)ₓ₂ (A2)
Q¹[-(OR^{f13})_{y3}—O—R⁴-L⁴-(R⁴¹-T⁴¹)ₓ₄]ᵣ₁ (A3)
wherein
R^{f1} is a fluoroalkyl group having 1 to 20 carbon atoms, and when there is a plurality of R^{f1}, the plurality of R^{f1} is the same as or different from each other;
R^{f11} is a fluoroalkylene group having 1 to 6 carbon atoms, and when there is a plurality of R^{f11}, the plurality of R^{f11} is the same as or different from each other;
R¹ is an alkylene group or a fluoroalkylene group, and when there is a plurality of R¹, the plurality of R¹ is the same as or different from each other;
L¹ is a single bond or a j+x1 valent organic group optionally having N, O, S, or Si and a branch point, wherein atoms bonded to R¹ and R¹¹ are each independently N, O, S, or Si, a carbon atom constituting the branch point, or a carbon atom having an oxo group (═O);
R¹¹ is an alkylene group in which an atom bonded to L¹ is optionally an etheric oxygen atom and which optionally has an etheric oxygen atom between carbon-carbon atoms;
T¹¹ is —SiR^{a11}_{z11}R^{a12}_{3-z11};
R^{a11} is a hydroxy group or a hydrolyzable group, and when there is a plurality of R^{a11}, the plurality of R^{a11} is the same as or different from each other;
R^{a12} is a non-hydrolyzable group, and when there is a plurality of R^{a12}, the plurality of R^{a12} is the same as or different from each other;
j is an integer of 1 or more;
z11 is an integer of 1 to 3;
x1 is an integer of 1 or more;
y1 is an integer of 1 or more, and when there is a plurality of y1, the plurality of y1 is the same as or different from each other;
R^{f12} is a fluoroalkylene group having 1 to 6 carbon atoms, and when there is a plurality of R^{f12}, the plurality of R^{f12} is the same as or different from each other;
R² and R³ are each independently an alkylene group or a fluoroalkylene group;
L² is a single bond or a 1+x2 valent organic group optionally having N, O, S, or Si and a branch point, wherein atoms bonded to R² and R²¹ are each independently N, O, S, or Si, a carbon atom constituting the branch point, or a carbon atom having an oxo group (═O);
R²¹ is an alkylene group in which an atom adjacent to L² is optionally an etheric oxygen atom and which optionally has an etheric oxygen atom between carbon-carbon atoms;
L³ is a single bond or a 1+x3 valent organic group optionally having N, O, S, or Si and a branch point, wherein atoms bonded to R³ and R³¹ are each independently N, O, S, or Si, a carbon atom constituting the branch point, or a carbon atom having an oxo group (═O);
R³¹ is an alkylene group in which an atom adjacent to L³ is optionally an etheric oxygen atom and which optionally has an etheric oxygen atom between carbon-carbon atoms;
T²¹ and T³¹ are each independently —SiR^{a21}_{z21}R^{a22}_{3-z21};
R^{a21} is a hydroxy group or a hydrolyzable group, and when there is a plurality of R^{a21}, the plurality of R^{a21} is the same as or different from each other;
R^{a22} is a non-hydrolyzable group, and when there is a plurality of R^{a22}, the plurality of R^{a22} is the same as or different from each other;
z21 is an integer of 1 to 3;
x2 and ×3 are each independently an integer of 1 or more;
y2 is an integer of 1 or more;
Q¹ is an r1 valent group having a branch point;
R^{f13} is a fluoroalkylene group having 1 to 6 carbon atoms, and when there is a plurality of R^{f13}, the plurality of R^{f13} is the same as or different from each other;
each R⁴ is independently an alkylene group or a fluoroalkylene group;
L⁴ is a single bond or a 1+x4 valent organic group optionally having N, O, S, or Si and a branch point, wherein atoms bonded to R⁴ and R⁴¹ are each independently N, O, S, or Si, a carbon atom constituting the branch point, or a carbon atom having an oxo group (═O);
R⁴¹ is an alkylene group in which an atom adjacent to L⁴ is optionally an etheric oxygen atom and which optionally has an etheric oxygen atom between carbon-carbon atoms;
T⁴¹ is —SiR^{a41}_{z41}R^{a42}_{3-z41};
R^{a41} is a hydroxy group or a hydrolyzable group, and when there is a plurality of R^{a41}, the plurality of R^{a41} is the same as or different from each other;
R^{a42} is a non-hydrolyzable group, and when there is a plurality of R^{a42}, the plurality of R^{a42} is the same as or different from each other;
z41 is an integer of 1 to 3;
x4 is an integer of 1 or more;
y3 is an integer of 1 or more; and
r1 is 3 or 4.

9. The surface treating agent according to claim 1, further comprising a liquid medium.

10. The surface treating agent according to claim 2, further comprising a liquid medium.

11. The surface treating agent according to claim 9, wherein the liquid medium is a fluorine-based organic solvent.

12. The surface treating agent according to claim 10, wherein the liquid medium is a fluorine-based organic solvent.

13. An article comprising a surface layer formed of the surface treating agent according to claim 1 on a substrate.

14. An article comprising a surface layer formed of the surface treating agent according to claim 2 on a substrate.

15. A method for producing an article, comprising forming a surface layer on a substrate by a dry coating method or a wet coating method using the surface treating agent according to claim 1.

16. A method for producing an article, comprising forming a surface layer on a substrate by a dry coating method or a wet coating method using the surface treating agent according to claim 2.
